(19) United States
(12) Patent Application Publication
(10) Pub. No.: US 2025/0338475 A1
(43) Pub. Date: Oct. 30, 2025

(54) SEMICONDUCTOR DEVICES AND FABRICATING METHODS THEREOF

(71) Applicant: YANGTZE MEMORY TECHNOLOGIES CO., LTD., Wuhan (CN)

(72) Inventors: Cheng Zhang, Wuhan (CN); Sen Yao, Wuhan (CN); Xiaoming Meng, Wuhan (CN); Qishi Liu, Wuhan (CN); Zhanhai Xiao, Wuhan (CN); Gang Li, Wuhan (CN)

(21) Appl. No.: 18/660,882

(22) Filed: May 10, 2024

(30) Foreign Application Priority Data
Apr. 29, 2024 (CN) 202410533611.6

(51) Int. Cl. H10B 12/00

(52) U.S. Cl. CPC H10B 12/315; H10D 1/042; H10D 1/043; H10D 1/714

(57) ABSTRACT

Semiconductor devices and fabricating methods are provided. In some implementations, a disclosed semiconductor device includes an array of vertical transistors, and an array of vertical capacitors. Each of the vertical capacitors includes a first electrode structure coupled with a corresponding one of the array of vertical transistors, and a second electrode structure electrically isolated from the first electrode structure. The first electrode structure has a first uneven sidewall along a vertical direction and facing the second electrode structure.

### CROSS-REFERENCE TO RELATED APPLICATIONS

This application claims the benefit of priority to Chinese Application No. 202410533611.6, filed on Apr. 29, 2024, which is incorporated herein by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

One aspect of the present disclosure provides a semiconductor device, comprising: an array of vertical transistors; and an array of vertical capacitors each comprising: a first electrode structure coupled with a corresponding one of the array of vertical transistors, and a second electrode structure electrically isolated from the first electrode structure, wherein the first electrode structure has a first uneven sidewall along a vertical direction and facing the second electrode structure.

In some implementations, each capacitor further comprises: a capacitor dielectric layer having an uneven thickness between the first electrode structure and the second electrode structure.

In some implementations, the second electrode structures of the array of vertical capacitors are connected with each other to form a common electrode.

In some implementations, the second electrode structure has a second uneven sidewall facing the first electrode structure.

In some implementations, the semiconductor device further comprises: a mesh structure in between adjacent vertical capacitors of the array of vertical capacitors, wherein the first electrode structure has a smooth sidewall facing the mesh structure.

In some implementations, the semiconductor device further comprises: a mesh structure in between adjacent vertical capacitors of the array of vertical capacitors, wherein a portion of the first electrode structure in contact with the mesh structure has a smooth sidewall.

In some implementations, the first uneven sidewall has a waved surface.

In some implementations, a lateral difference between a peak position and a trough position of the waved surface of the first uneven sidewall is in a range between about 10 nm and about 15 nm; and a vertical difference between adjacent two peak positions of the waved surface of the first uneven sidewall is in a range between about 10 nm and about 30 nm.

In some implementations, the first uneven sidewall has a randomly undulating surface or includes implanted ions with a randomly distributed concentration.

In some implementations, a lateral difference between a peak position and a trough position of the randomly undulating surface of the first uneven sidewall is in a range between about 2 nm and about 8 nm; and the implanted ions are phosphorus ions or boron ions.

Another aspect of the present disclosure provides a method of forming a semiconductor device, comprising: forming an array of vertical transistors; and forming an array of first electrode structures each extending along a vertical direction and coupled with a corresponding one of the array of vertical transistors, wherein each first electrode structure has a first uneven sidewall; forming a capacitor dielectric layer to cover the array of first electrode structures; and forming a common electrode structure including a plurality of second electrode structures, wherein each of the plurality of second electrode structures and a corresponding one of the array of first electrode structures form a vertical capacitor coupled with the corresponding one of the array of vertical transistors.

In some implementations, forming the array of first electrode structures comprises: forming an insulating layer on the array of vertical transistors; forming an array of through holes in the insulating layer to expose the array of vertical transistors, wherein each through hole has an uneven sidewall along the vertical direction; and depositing one or more conductive materials into the array of through holes to form the array of first electrode structures.

In some implementations, forming an array of through holes comprises: performing a plurality of cycles of etching processes, each cycle of etching process comprising: removing a portion of the insulating layer to increase a depth of each through hole; forming a passivating layer on a sidewall and a bottom surface of each through hole; and removing a portion of the passivating layer on the bottom surface of each through hole.

In some implementations, forming an array of through holes comprises: performing an ion implanting process to sidewalls of the array of through holes, such that each through hole has the uneven sidewall.

In some implementations, performing the ion implanting process comprises: implanting phosphorus ions or boron ions to the sidewalls of the array of through holes.

In some implementations, forming the array of first electrode structures comprises: performing an ion implanting process to sidewalls of the array of first electrode structures, such that each first electrode structure has the first uneven sidewall.

In some implementations, performing the ion implanting process comprises: implanting phosphorus ions or boron ions to the sidewalls of the array of first electrode structures.

In some implementations, before forming the array of first electrode structures, the method further comprises: forming an insulating layer on the array of vertical transistors; forming a mesh structure in the insulating layer; and forming an array of through holes each vertically extending through the insulating layer and the mesh structure to expose the array of vertical transistors.

In some implementations, before performing the ion implanting process, the method further comprises: depositing one or more conductive materials into the array of through holes to form the array of first electrode structures; and removing portions of the mesh structure to expose the sidewalls of the array of first electrode structures.

Another aspect of the present disclosure provides a system, comprising: a memory device configured to store data, the memory device comprising: an array of vertical transistors; and an array of vertical capacitors each comprising: a first electrode structure coupled with a corresponding one of the array of vertical transistors, and a second electrode structure electrically isolated from the first electrode structure, wherein the first electrode structure has a first uneven sidewall along a vertical direction and facing the second electrode structure; and a memory controller electrically connected to the memory device and configured to control the memory device.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a memory device including an array of memory cells, according to some implementations of the present disclosure.

FIG. 2 illustrates a schematic side view of a cross-section of a semiconductor structure, according to some implementations of the present disclosure.

FIG. 3 illustrates a schematic side view of a cross-section of a semiconductor structure, according to some implementations of the present disclosure.

FIG. 4 illustrates a schematic side view of a cross-section of a semiconductor structure, according to some implementations of the present disclosure.

FIG. 5 illustrates a block diagram of a system having a memory device, according to some implementations of the present disclosure.

FIG. 6 illustrates a flowchart of a fabricating method for forming a semiconductor structure, according to some implementations of the present disclosure.

FIGS. 7A-7G each illustrates a schematic side cross-sectional view of a semiconductor structure at a certain fabricating stage of the method shown in FIG. 6, according to various implementations of the present disclosure.

FIG. 8 illustrates a flowchart of a fabricating method for forming a semiconductor structure, according to some implementations of the present disclosure.

FIGS. 9A-9G each illustrates a schematic side cross-sectional view of a semiconductor structure at a certain fabricating stage of the method shown in FIG. 8, according to various implementations of the present disclosure.

FIG. 10 illustrates a flowchart of a fabricating method for forming a semiconductor structure, according to some implementations of the present disclosure.

FIGS. 11A-11G each illustrates a schematic side cross-sectional view of a semiconductor structure at a certain fabricating stage of the method shown in FIG. 10, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as dynamic radon access memory (DRAM). In a one-transistor-one-capacitor (1T1C) DRAM structure, the data are stored in the capacitors.

As DRAM dimensions continue to shrink, the height of the storage node (SN) faces challenges in further increase due to constraints such as aspect ratio (AR) and bending. Typically, to enhance or maintain capacitance, there's a need to increase the k-value of the dielectric layer between the capacitor electrodes. However, increasing the k-value or increasing the height of capacitance can become difficult due to rising fabricating process complexities. Consequently, capacitance values struggle to increase, leading to a significant bit line (BL) to BL coupling. Thus, the quest to optimize SN capacitance can be advantageous for sense margin, while navigating technological hurdles underscores the intricate balance between miniaturization and functionality in DRAM design.

To address one or more of the aforementioned issues, the present disclosure introduces a solution in which a Bosch process can be used in the capacitance hole etching process. By using deep reactive ion etching steps, the hard mask (HM) consumption can be effectively diminished, and the thickness of the HM layer can be effectively reduced. Further, the Bosch process can form a cyclic protrusion structure along the sidewalls of the capacitance holes. This structure enhances the surface area of the capacitance electrodes, thereby increasing capacitance without altering the height or k-value, ultimately bolstering the sense margin. Moreover, the hard mask oxide (HMOX) layer can be omitted in the disclosed fabricating process, thereby omitting corresponding etching and deposition processes. In addition, the polysilicon layer and the Draco HM layer can be thinned to lower the depth-to-width ratio, thereby decreasing the complexity of both the DRACO HM etching and the capacitance hole etching processes. This streamlining of processes not only contributes to cost savings but also enhances manufacturability by simplifying the fabrication steps involved in producing DRAM components.

It is noted that, consistent with the scope of the present disclosure, according to some implementations of the present disclosure, the memory cell array having vertical transistors each including a semiconductor layer extending in a vertical direction, and a gate structure beside the semiconductor layer or surrounded by the semiconductor layer. In some implementations, the word lines and bit lines connected to the vertical transistors are arranged along a first lateral direction and a second lateral direction, respectively. Each of the semiconductor bodies of the array of vertical transistors extends along a vertical direction. By using such an arrangement, memory area efficiency can be increased. Further, the memory cell array and the peripheral circuits can be formed separately on different wafers, such that the fabricating processes of the memory cell array and the peripheral circuits do not affect each other, and the memory area efficiency can be further increased.

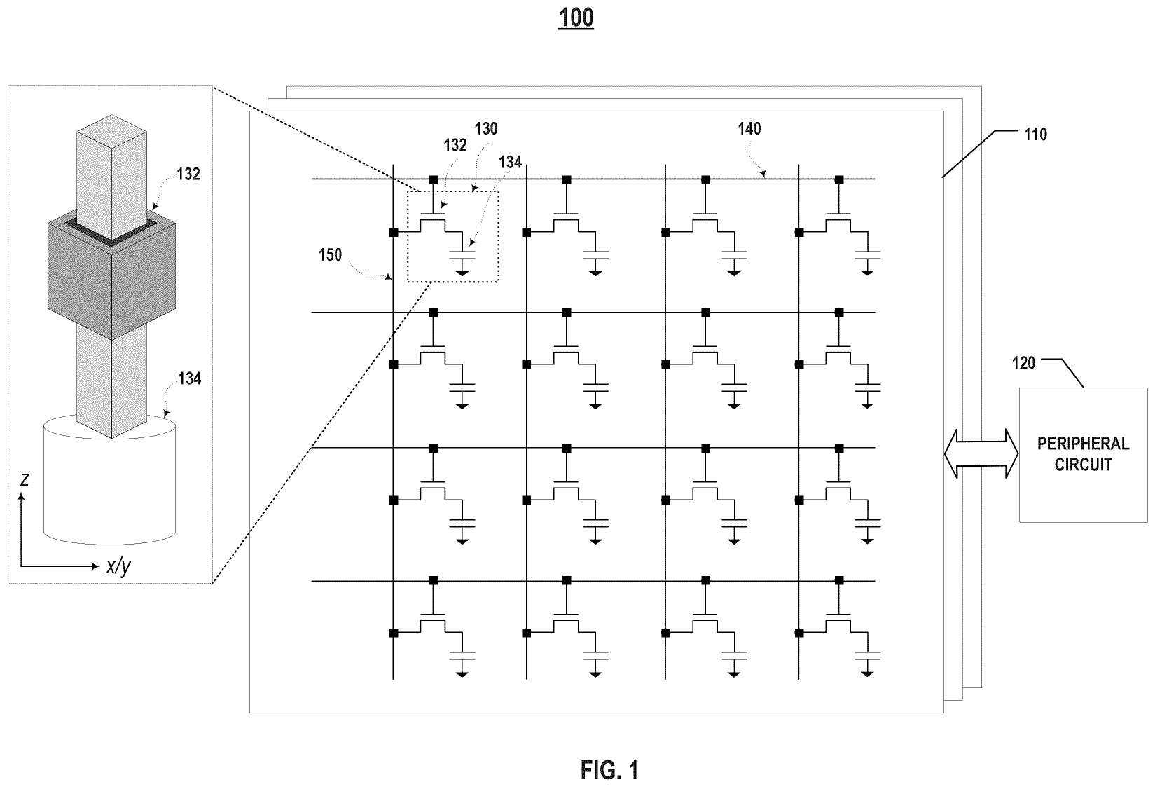

FIG. 1 illustrates a schematic diagram of a semiconductor device 100 including peripheral circuits and an array of memory cells each having a vertical transistor, according to some aspects of the present disclosure. Semiconductor device 100 can include a memory cell array 110 and peripheral circuits 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell. As shown in FIG. 1, memory cells 130 can be arranged in a two-dimensional (2D) array having rows and columns. Peripheral circuits 120 can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits 120 can use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Semiconductor device 100 can include word lines 140 coupling peripheral circuits 120 and memory cell array 110 for controlling the switch of vertical transistors 132 in memory cells 130 located in a row, as well as bit lines 150 coupling peripheral circuits 120 and memory cell array 110 for sending data to and/or receiving data from memory cells 130 located in a column. That is, each word line 140 is coupled to a respective row of memory cells 130, and each bit line 150 is coupled to a respective column of memory cells 130.

Consistent with the scope of the present disclosure, vertical transistors 132, such as vertical metal-oxide-semiconductor field-effect transistors (MOSFETs), can replace the conventional planar transistors as the pass transistors of memory cells 130 to reduce the area occupied by the pass transistors, the coupling capacitance, as well as the interconnect routing complexity, as described below in detail. As shown in FIG. 1, in some implementations, different from planar transistors in which the active regions are formed in the substrates, vertical transistor 132 includes a semiconductor body extending vertically (in the z-direction) above the substrate (not shown). That is, the semiconductor body can extend above the top surface of the substrate, exposing not only the top surface of the semiconductor body but also one or more of its side surfaces. As shown in FIG. 1, for example, the semiconductor body can have a cuboid shape, exposing four sides. It is understood that the semiconductor body may take any suitable shape, such as a polyhedron shape or a cylinder shape. That is, the cross-section of the semiconductor body in the plan view (e.g., in the x-y plane) can have a square shape, a rectangular shape (or a trapezoidal shape), a circular shape (or an oval shape), or any other suitable shapes. It is understood that consistent with the scope of the present disclosure, semiconductor layers that have a circular or oval shape of their cross-sections in the plan view may still be considered to have multiple sides, allowing the gate structures to be coupled with more than one side of the semiconductor layers. As described below with respect to the fabrication process, the semiconductor body can be formed from the substrate (e.g., by etching or epitaxy) and thus, has the same semiconductor material (e.g., silicon crystalline silicon) as the substrate (e.g., a silicon substrate).

As shown in FIG. 1, vertical transistor 132 can also include a gate structure coupled with one or more sides of the semiconductor body, i.e., in one or more planes of the side surface(s) of the active region. In other words, the active region of vertical transistor 132, i.e., semiconductor body, can be at least partially surrounded by a gate structure. The gate structure can include a gate dielectric over one or more sides of the semiconductor body, e.g., coupled with four side surfaces of the semiconductor body as shown in FIG. 1. The gate structure can also include a gate electrode over and coupled with the gate dielectric. The gate dielectric can include any suitable dielectric materials, such as silicon oxide, silicon nitride, silicon oxynitride, or high-k dielectrics. The gate electrode can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

As shown in FIG. 1, vertical transistor 132 can further include a pair of a source and a drain (S/D, dope regions, a.k.a., source electrode and drain electrode) formed at the two ends of the semiconductor body in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by the gate structure in the vertical direction (the z-direction). As a result, one or more channels (not shown) of vertical transistor 132 can be formed in the semiconductor body vertically between the source and drain when a gate voltage applied to the gate electrode of the gate structure exceeds the threshold voltage of vertical transistor 132.

In some implementations, as shown in FIG. 1, vertical transistor 132 is a multi-gate transistor. This means that the gate structure can be coupled with more than one side of the semiconductor body (e.g., four sides in FIG. 1) to form more than one gate, allowing for the formation of multiple channels between the source and drain during operation. Unlike planar transistors that include only a single planar gate (resulting in a single planar channel), vertical transistor 132 shown in FIG. 1 can include multiple vertical gates on multiple sides of the semiconductor body due to the semiconductor structure of the semiconductor body and the gate structure that surrounds the multiple sides of the semiconductor body. Compared with planar transistors, vertical transistor 132 shown in FIG. 1 can have a larger gate control area, enabling better channel control with a smaller subthreshold swing. During the off state, since the channel is fully depleted, the leakage current of vertical transistor 132 can be significantly reduced as well. As described in detail below, the multi-gate vertical transistors can include double-gate vertical transistors (e.g., dual-side gate vertical transistors), tri-gate vertical transistors (e.g., tri-side gate vertical transistors), and GAA vertical transistors.

While vertical transistor 132 is shown as a multi-gate transistor in FIG. 1, it is understood that the vertical transistors disclosed herein may also include single-gate transistors, as described in detail below. That is, the gate structure may be coupled with a single side of the semiconductor body, for example, for the purpose of increasing the transistor and memory cell density. It is also understood that while the gate dielectric is shown as being separate (i.e., a separate structure) from other gate dielectrics of adjacent vertical transistors (not shown), the gate dielectric may be part of a continuous dielectric layer having multiple gate dielectrics of vertical transistors.

As shown in FIG. 1, storage unit 134 can be coupled to the source or the drain of vertical transistor 132. Storage unit 134 can include any devices that are capable of storing binary data (e.g., 0 and 1), including but not limited to capacitors for DRAM cells and FRAM cells, as well as PCM elements for PCM cells. Peripheral circuits 120 can be coupled to memory cell array 110 through bit lines 150, word lines 140, and any other suitable metal wirings. As described above, peripheral circuits 120 can include any suitable circuits for facilitating the operations of memory cell array 110 by applying and sensing voltage signals and/or current signals through word lines 140 and bit lines 150 to and from each memory cell 130. Peripheral circuits 120 can include various types of peripheral circuits formed using CMOS technologies.

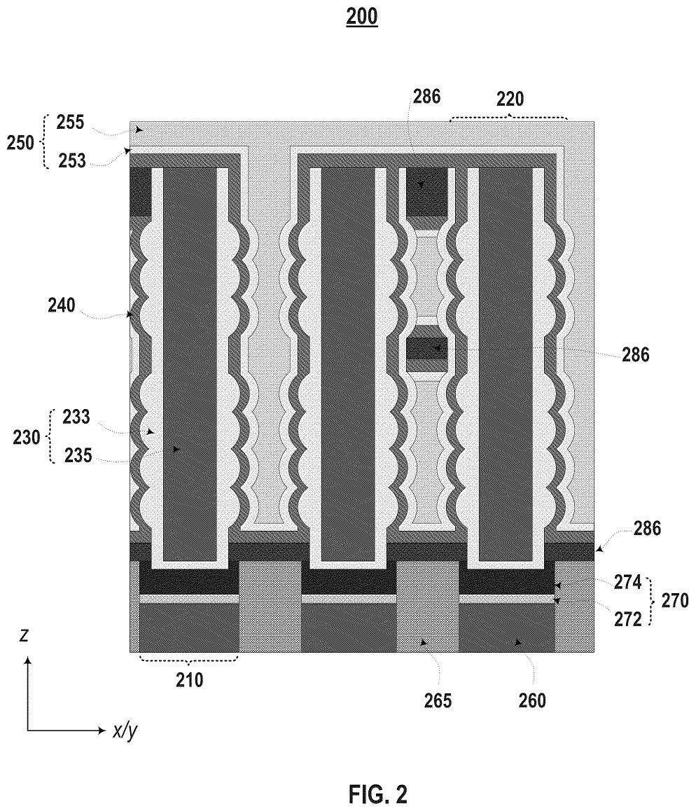

FIG. 2 illustrates a side view of a cross-section of a semiconductor structure 200, according to some aspects of the present disclosure. It is understood that FIG. 2 is for illustrative purposes only, may not necessarily reflect the actual device structure (e.g., interconnections) in practice, and may not show all components of semiconductor structure 200.

Semiconductor structure 200 can include a DRAM device in which memory cells are provided in the form of an array of DRAM cells each including a vertical transistor 210 and capacitor 220 coupled to the vertical transistor 210. The DRAM cell can be a 1T1C cell consisting of one transistor and one capacitor. It is understood that the DRAM cell may have any suitable configurations, such as 2T1C cell, 3T1C cell, etc. Vertical transistor 210 can be a MOSFET used to switch a respective DRAM cell. In some implementations, vertical transistor 210 includes a semiconductor layer 260 (i.e., the active region in which multiple channels can form) extending vertically (in the z-direction), and a gate structure coupled with one or more sides of semiconductor layer 260.

In some implementations, semiconductor layer 260 can include any suitable semiconductor material, such as silicon (e.g., single crystalline silicon, c-Si), silicon germanium (SiGe), gallium arsenide (GaAs), germanium (Ge), silicon-on-insulator (SOI), etc. In some implementations, semiconductor layer 260 can include a metal oxide semiconductor material, and a leakage value of the semiconductor layer 260 is lower than a pico-ampere. For example, semiconductor layer 260 can be one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

In some implementations, semiconductor layer 260 of each vertical transistor 210 extends in a vertical direction (the z-direction). Adjacent semiconductor layer 260 of neighboring vertical transistors 210 can be separated from each other by dielectric spacer 265. Vertical transistor 210 can further include a source and a drain disposed at the two ends (the upper end and lower end) of semiconductor layer 260, respectively, in the vertical direction (the z-direction). The source and drain can be doped with N-type dopants (e.g., P or As) or P-type dopants (e.g., B or Ga) at a desired doping level. In some implementations, the source is coupled to capacitor 220, and the drain is coupled to a bit line (not shown). It is noted that FIG. 2 only illustrates the source ends of the semiconductor layers 260 that are coupled to capacitors 220, while other portions of semiconductor layers 260 are omitted for simplicity.

In some implementations, the gate structure of each vertical transistor 210 can include a gate dielectric (not shown) and a gate electrode (not shown). In some implementations, the gate dielectric can include dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, the gate electrode can include conductive materials including, but not limited to, W, Co, Cu, Al, TiN, TaN, polysilicon, silicide, or any combination thereof. In some implementations, the gate electrode can include multiple conductive layers, such as a W layer over a TiN layer. In one example, the gate structure may be a “gate oxide/gate poly” gate in which the gate dielectric includes silicon oxide, and the gate electrode includes doped polysilicon. In another example, the gate structure may be a high-k metal gate (HKMG) in which the gate dielectric includes a high-k dielectric and gate electrode includes a metal. It is understood that the vertical transistors 210 can be single-gate transistors, double-gate transistors, or gate-all-around transistors. As such, the gate structure of the vertical transistor 210 can be located at one or more lateral sides of the semiconductor layer 260.

As shown in FIG. 2, the semiconductor layer 260 can be electrically coupled to the capacitors 220 through source node (SN) contacts 270. During the read and write operations, the selected vertical transistor 210 is activated by applying an appropriate voltage to its gate structure. When activated, the selected vertical transistor 210 connects the corresponding capacitor 220 to the bit line, allowing the stored charge in the corresponding capacitor 220 to be read or updated. In some implementations, source node (SN) contacts 270 can be a multi-layer conductive structure. For example, as shown in FIG. 2, the SN contact 270 can include a silicide layer (e.g., cobalt silicide (CoSi)) 272 and a metal layer (e.g., tungsten (W)) 274.

As shown in FIG. 2, in some implementations, capacitor 220 includes a first electrode structure 230, a second electrode structure 250, and a capacitor dielectric layer 240 between the first electrode structure 230 and the second electrode structure 250. That is, capacitor 220 can be a vertical capacitor in which the first and second electrode structures 230 and 250 and the capacitor dielectric layer 240 can extend vertically (in the z-direction). In some implementations, each first electrode structure 230 is coupled to the source of a respective vertical transistor 210 in the same DRAM cell through the SN contact 270, while the second electrode structures 250 of multiple capacitors 220 can be connected with each other to form a common second electrode coupled to a common reference voltage, e.g., a common ground.

In some implementations, the first electrode structures 230 and/or the second electrode structure 250 can include conductive materials including, but not limited to, W, Co, Cu, Al, TiN, TaN, polysilicon, silicide, or any combination thereof. In some implementations, the first electrode structures 230 and/or the second electrode structure 250 include a multiple-layer structure, each layer of the multiple-layer structure comprising one of TiN, TaN, carbon, polysilicon, metal, metal compounds, and silicide. For example, as shown in FIG. 2, the first electrode structure 230 includes a first conductive layer 233 in contact with the capacitor dielectric layer 240 and the SN contact 270 directly, and a second conductive layer 235 surrounded by first conductive layer 233. The second electrode structure 250 includes a third conductive layer 253 in contact with the capacitor dielectric layer 240 directly, and a fourth conductive layer 255. In some implementations, the material of each layer of the multiple-layer structure is different from the material of other layers. For example, the first conductive layer 233 and the third conductive layer 253 are TiN, the second conductive layer 235 is polysilicon, and the fourth conductive layer 255 is GeSi. In some implementations, capacitor dielectric layer 240 includes dielectric materials, such as silicon oxide, silicon nitride, or high-k dielectrics including, but not limited to, Al₂O₃, HfO₂, Ta₂O₅, ZrO₂, TiO₂, or any combination thereof.

As shown in FIG. 2, in some implementations, the first electrode structure 230 includes a first uneven sidewall along the vertical direction (i.e., z-direction) and facing the second electrode structure 250. In some implementations, the second electrode structure 250 includes a second uneven sidewall along the vertical direction (i.e., z-direction) and facing the first electrode structure 230. In some implementations, the capacitor dielectric layer 240 includes sidewalls along the vertical direction (i.e., z-direction) and facing the first electrode structure 230 and the second electrode structure 250, respectively. In some implementations, the capacitor dielectric layer 240 can have an uneven thickness between the first electrode structure 230 and the second electrode structure 250. In some implementations, the first uneven sidewall of the first electrode structure 230 has a waved surface, as shown in FIG. 2. Specifically, a lateral difference between a peak position and a trough position of the waved surface of the first uneven sidewall is in a range between about 10 nm and about 15 nm, and a vertical difference between adjacent two peak positions of the waved surface of the first uneven sidewall is in a range between about 10 nm and about 30 nm. Similarly, the second uneven sidewall of the second electrode structure 250, and the uneven sidewalls of the capacitor dielectric layer 240 can also have waved surfaces, as shown in FIG. 2.

In some implementations, capacitors 220 have a relatively large height in the vertical direction (i.e., z-direction). Thus, the number of waves of the uneven sidewalls of the first electrode structure 230 and the second electrode structure 250 can be relatively large. Therefore, the surface area between the first electrode structure 230 and the second electrode structure 250 can be effectively increased within a same height of the capacitors 220, thereby increasing capacitance without altering the height or k-value, ultimately bolstering the sense margin. It is noted that, such a structure requires mechanical stabilization with one or more mesh layers 286, as shown in FIG. 2. As such, the spacing between capacitors 220 remains consistent, thereby preventing capacitor corruption. Without mesh layers 286, capacitors 220 might lean over and come in to contact with adjacent capacitors 220. Mesh layer 286 can include any suitable dielectric materials with a Mohs scale larger than that of silicon oxide, which has a Mohs scale of around six. In some implementations, mesh layers 286 can include silicon nitride, silicon carbide, corundum, boron carbide, boron nitride, or any combination thereof. In some implementations, as the aspect ratio of capacitors 220 varies, the number of levels of mesh layers 286 can be adjusted accordingly to ensure mechanical stability.

In some implementations, one or more peripheral circuits (not shown) can be coupled to the vertical transistors 210 and the capacitors 220 through any other suitable conductive wirings. It is noted that the one or more peripheral circuits can include any suitable circuits for facilitating the operations of vertical transistors 210 and the capacitors 220 by applying voltage signals and/or current signals to and from the vertical transistors 210 and the capacitors 220. The one or more peripheral circuits can include various types of peripheral circuits formed using CMOS technologies.

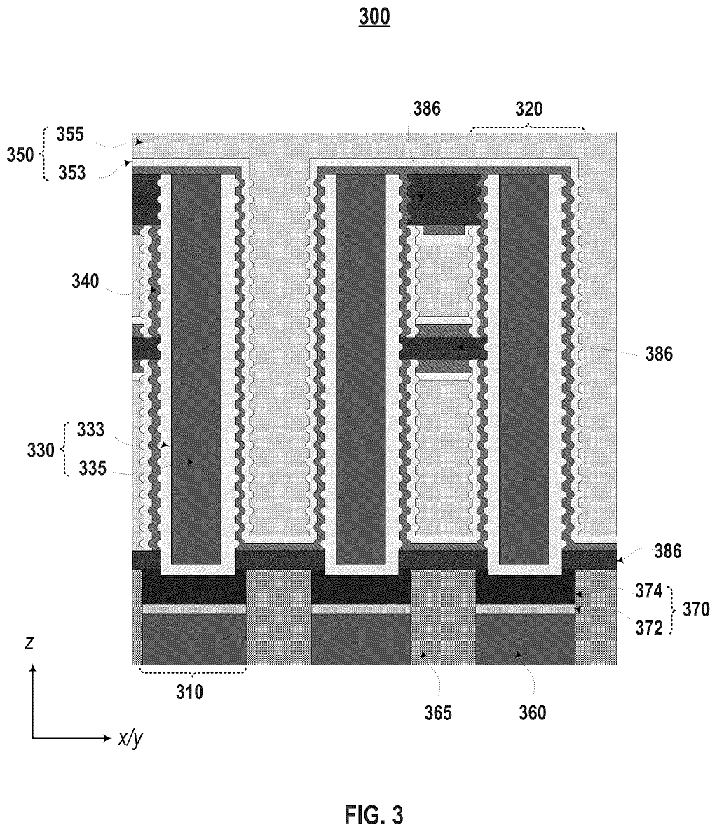

FIG. 3 illustrates a side view of a cross-section of a semiconductor structure 300, according to some aspects of the present disclosure. It is understood that FIG. 3 is for illustrative purposes only, may not necessarily reflect the actual device structure (e.g., interconnections) in practice, and may not show all components of semiconductor structure 300.

Semiconductor structure 300 can include a DRAM device in which memory cells are provided in the form of an array of DRAM cells each including a vertical transistor 310 and capacitor 320 coupled to the vertical transistor 310. The DRAM cell can be a 1T1C cell consisting of one transistor and one capacitor. It is understood that the DRAM cell may have any suitable configurations, such as 2T1C cell, 3T1C cell, etc. Vertical transistor 310 can be a MOSFET used to switch a respective DRAM cell. In some implementations, vertical transistor 310 includes a semiconductor layer 360 (i.e., the active region in which multiple channels can form) extending vertically (in the z-direction), and a gate structure coupled with one or more sides of semiconductor layer 360.

In some implementations, semiconductor layer 360 can include any suitable semiconductor material, such as silicon (e.g., c-Si), SiGe, GaAs, Ge, SOI, etc. In some implementations, semiconductor layer 360 can include a metal oxide semiconductor material, and a leakage value of the semiconductor layer 360 is lower than a pico-ampere. For example, semiconductor layer 360 can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc. In some implementations, semiconductor layer 360 of each vertical transistor 310 extends in a vertical direction (the z-direction). Adjacent semiconductor layer 360 of neighboring vertical transistors 310 can be separated from each other by dielectric spacer 365. Vertical transistor 310 can further include a source and a drain disposed at the two ends (the upper end and lower end) of semiconductor layer 360, respectively, in the vertical direction (the z-direction). The source and drain can be doped with N-type dopants (e.g., P or As) or P-type dopants (e.g., B or Ga) at a desired doping level. In some implementations, the source is coupled to capacitor 320, and the drain is coupled to a bit line (not shown). It is noted that FIG. 3 only illustrates the source ends of semiconductor layers 360 that are coupled to capacitors 320, while other portions of semiconductor layers 360 are omitted for simplicity.

In some implementations, the gate structure of each vertical transistor 310 can include a gate dielectric (not shown) and a gate electrode (not shown). In some implementations, the gate dielectric can include dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the gate electrode can include conductive materials including, but not limited to, W, Co, Cu, Al, TiN, TaN, polysilicon, silicide, or any combination thereof. In some implementations, the gate electrode can include multiple conductive layers, such as a W layer over a TiN layer. In one example, the gate structure may be a “gate oxide/gate poly” gate in which the gate dielectric includes silicon oxide, and the gate electrode includes doped polysilicon. In another example, the gate structure may be a high-k metal gate (HKMG) in which the gate dielectric includes a high-k dielectric, and the gate electrode includes a metal. It is understood that the vertical transistors 310 can be single-gate transistors, double-gate transistors, or gate-all-around transistors. As such, the gate structure of the vertical transistor 310 can be located at one or more lateral sides of the semiconductor layer 360.

As shown in FIG. 3, the semiconductor layer 360 can be electrically coupled to the capacitors 320 through SN contacts 370. During the read and write operations, the selected vertical transistor 310 is activated by applying an appropriate voltage to its gate structure. When activated, the selected vertical transistor 310 connects the corresponding capacitor 320 to the bit line, allowing the stored charge in the corresponding capacitor 320 to be read or updated. In some implementations, SN contacts 370 can be a multi-layer conductive structure. For example, as shown in FIG. 3, the SN contact 370 can include a silicide layer (e.g., CoSi) 372 and a metal layer (e.g., W) 374.

As shown in FIG. 3, in some implementations, capacitor 320 includes a first electrode structure 330, a second electrode structure 350, and a capacitor dielectric layer 340 between first electrode structure 330 and second electrode structure 350. That is, the capacitor 320 can be a vertical capacitor in which first and the second electrode structures 330 and 350 and the capacitor dielectric layer 340 can extend vertically (in the z-direction). In some implementations, each first electrode structure 330 is coupled to the source of a respective vertical transistor 310 in the same DRAM cell through the SN contact 370, while the second electrode structures 350 of multiple capacitors 320 can be connected with each other to form a common second electrode coupled to a common reference voltage, e.g., a common ground.

In some implementations, the first electrode structures 330 and/or the second electrode structure 350 can include conductive materials including, but not limited to, W, Co, Cu, Al, TiN, TaN, polysilicon, silicide, or any combination thereof. In some implementations, the first electrode structures 330 and/or the second electrode structure 350 include a multiple-layer structure, each layer of the multiple-layer structure comprising one of TiN, TaN, carbon, polysilicon, metal, metal compounds, and silicide. For example, as shown in FIG. 3, the first electrode structure 330 includes a first conductive layer 333 in contact with the capacitor dielectric layer 340 and the SN contact 370 directly, and a second conductive layer 335 surrounded by first conductive layer 333. The second electrode structure 350 includes a third conductive layer 353 in contact with the capacitor dielectric layer 340 directly, and a fourth conductive layer 355. In some implementations, the material of each layer of the multiple-layer structure is different from the material of other layers. For example, the first conductive layer 333 and the third conductive layer 353 are TiN, the second conductive layer 335 is polysilicon, and the fourth conductive layer 355 is GeSi. In some implementations, capacitor dielectric layer 340 includes dielectric materials, such as silicon oxide, silicon nitride, or high-k dielectrics including, but not limited to, Al₂O₃, HfO₂, Ta₂O₅, ZrO₂, TiO₂, or any combination thereof.

As shown in FIG. 3, in some implementations, the first electrode structure 330 includes a first uneven sidewall along the vertical direction (i.e., z-direction) and facing the second electrode structure 350. In some implementations, the second electrode structure 350 includes a second uneven sidewall along the vertical direction (i.e., z-direction) and facing the first electrode structure 330. In some implementations, the capacitor dielectric layer 340 includes sidewalls along the vertical direction (i.e., z-direction) and facing the first electrode structure 330 and the second electrode structure 350, respectively. In some implementations, the capacitor dielectric layer 340 can have an uneven thickness between the first electrode structure 330 and the second electrode structure 350. In some implementations, the first uneven sidewall of the first electrode structure 330, the second uneven sidewall of the second electrode structure 350, and/or the uneven sidewalls of the capacitor dielectric layer 340 can have randomly undulating surfaces. In some implementations, at least one of the first uneven sidewalls of the first electrode structure 330 and the second uneven sidewalls of the second electrode structure 350 can include implanted ions with a randomly distributed concentration.

In some implementations, capacitors 320 have a relatively large height in the vertical direction (i.e., z-direction). Thus, the number of waves of the uneven sidewalls of the first electrode structure 330 and the second electrode structure 350 can be relatively large. Therefore, the surface area between the first electrode structure 330 and the second electrode structure 350 can be effectively increased within a same height of the capacitors 320, thereby increasing capacitance without altering the height or k-value, ultimately bolstering the sense margin. It is noted that such a structure requires mechanical stabilization with one or more mesh layers 386, as shown in FIG. 3. As such, the spacing between capacitors 320 remains consistent, thereby preventing capacitor corruption. Without mesh layers 386, the capacitors 320 might lean over and come in to contact with adjacent capacitors 320. Mesh layer 386 can include any suitable dielectric materials with a Mohs scale larger than that of silicon oxide, which has a Mohs scale of around six. In some implementations, mesh layers 386 can include silicon nitride, silicon carbide, corundum, boron carbide, boron nitride, or any combination thereof. In some implementations, as the aspect ratio of the capacitors 320 varies, the number of levels of mesh layers 386 can be adjusted accordingly to ensure mechanical stability. In some implementations, the mesh layers 386 can laterally penetrate through the capacitor dielectric layer 340 and be in direct contact with the first electrode structure 330. In such implementations, the contact surface of the mesh layers 386 facing the first electrode structure 330 can be randomly undulating surfaces, as shown in FIG. 3.

In some implementations, one or more peripheral circuits (not shown) can be coupled to the vertical transistors 310 and the capacitors 320 through any other suitable conductive wirings. It is noted that the one or more peripheral circuits can include any suitable circuits for facilitating the operations of vertical transistors 310 and the capacitors 320 by applying voltage signals and/or current signals to and from the vertical transistors 310 and the capacitors 320. The one or more peripheral circuits can include various types of peripheral circuits formed using CMOS technologies.

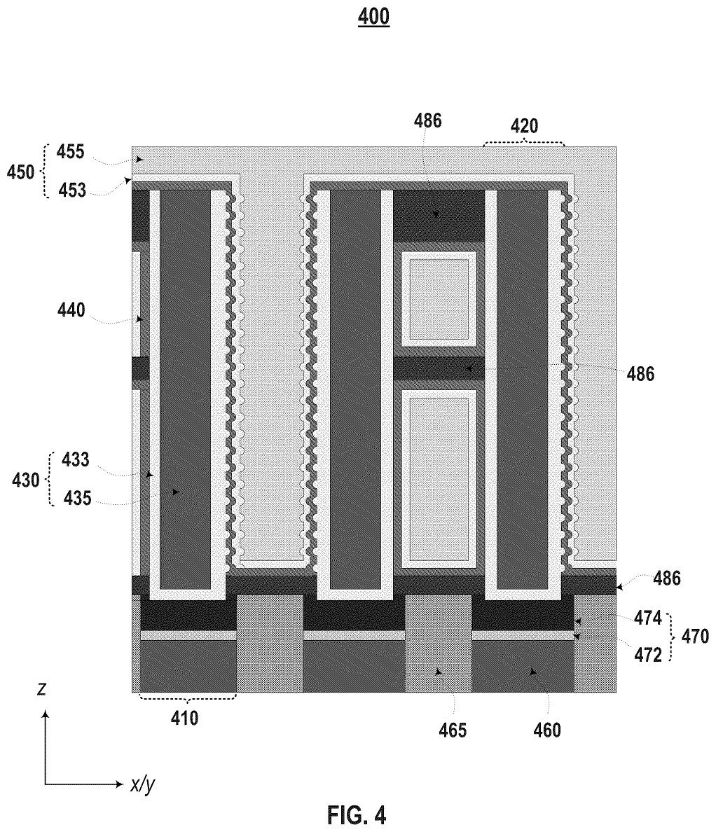

FIG. 4 illustrates a side view of a cross-section of a semiconductor structure 400, according to some aspects of the present disclosure. It is understood that FIG. 4 is for illustrative purposes only, may not necessarily reflect the actual device structure (e.g., interconnections) in practice, and may not show all components of semiconductor structure 400.

Semiconductor structure 400 can include a DRAM device in which memory cells are provided in the form of an array of DRAM cells each including a vertical transistor 410 and capacitor 420 coupled to the vertical transistor 410. The DRAM cell can be a 1T1C cell consisting of one transistor and one capacitor. It is understood that the DRAM cell may have any suitable configurations, such as 2T1C cell, 3T1C cell, etc. Vertical transistor 410 can be a MOSFET used to switch a respective DRAM cell. In some implementations, vertical transistor 410 includes a semiconductor layer 460 (i.e., the active region in which multiple channels can form) extending vertically (in the z-direction), and a gate structure coupled with one or more sides of semiconductor layer 460.

In some implementations, semiconductor layer 460 can include any suitable semiconductor material, such as silicon (e.g., c-Si), SiGe, GaAs, Ge, SOI, etc. In some implementations, semiconductor layer 460 can include a metal oxide semiconductor material, and a leakage value of the semiconductor layer 460 is lower than a pico-ampere. For example, semiconductor layer 360 can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc. In some implementations, semiconductor layer 460 of each vertical transistor 410 extends in a vertical direction (the z-direction). Adjacent semiconductor layer 460 of neighboring vertical transistors 410 can be separated from each other by dielectric spacer 465. Vertical transistor 410 can further include a source and a drain disposed at the two ends (the upper end and lower end) of semiconductor layer 460, respectively, in the vertical direction (the z-direction). The source and drain can be doped with N-type dopants (e.g., P or As) or P-type dopants (e.g., B or Ga) at a desired doping level. In some implementations, the source is coupled to capacitor 420, and the drain is coupled to a bit line (not shown). It is noted that FIG. 4 only illustrates the source ends of semiconductor layers 460 that are coupled to capacitors 420, while other portions of semiconductor layers 460 are omitted for simplicity.

In some implementations, the gate structure of each vertical transistor 410 can include a gate dielectric (not shown) and a gate electrode (not shown). In some implementations, the gate dielectric can include dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the gate electrode can include conductive materials including, but not limited to, W, Co, Cu, Al, TiN, TaN, polysilicon, silicide, or any combination thereof. In some implementations, the gate electrode can include multiple conductive layers, such as a W layer over a TiN layer. In one example, the gate structure may be a “gate oxide/gate poly” gate in which the gate dielectric includes silicon oxide, and the gate electrode includes doped polysilicon. In another example, the gate structure may be a high-k metal gate (HKMG) in which the gate dielectric includes a high-k dielectric, and the gate electrode includes a metal. It is understood that the vertical transistors 410 can be single-gate transistors, double-gate transistors, or gate-all-around transistors. As such, the gate structure of the vertical transistor 410 can be located at one or more lateral sides of the semiconductor layer 460.

As shown in FIG. 4, the semiconductor layer 460 can be electrically coupled to the capacitors 420 through SN contacts 470. During the read and write operations, the selected vertical transistor 410 is activated by applying an appropriate voltage to its gate structure. When activated, the selected vertical transistor 410 connects the corresponding capacitor 420 to the bit line, allowing the stored charge in the corresponding capacitor 420 to be read or updated. In some implementations, SN contacts 470 can be a multi-layer conductive structure. For example, as shown in FIG. 4, the SN contact 470 can include a silicide layer (e.g., CoSi) 472 and a metal layer (e.g., W) 474.

As shown in FIG. 4, in some implementations, capacitor 420 includes a first electrode structure 430, a second electrode structure 450, and a capacitor dielectric layer 440 between the first electrode structure 430 and the second electrode structure 450. That is, the capacitor 420 can be a vertical capacitor in which first and the second electrode structures 430 and 450 and the capacitor dielectric layer 440 can extend vertically (in the z-direction). In some implementations, each first electrode structure 430 is coupled to the source of a respective vertical transistor 410 in the same DRAM cell through the SN contact 470, while the second electrode structures 450 of multiple capacitors 420 can be connected with each other to form a common second electrode coupled to a common reference voltage, e.g., a common ground.

In some implementations, the first electrode structures 430 and/or the second electrode structure 450 can include conductive materials including, but not limited to, W, Co, Cu, Al, TiN, TaN, polysilicon, silicide, or any combination thereof. In some implementations, the first electrode structures 430 and/or the second electrode structure 450 include a multiple-layer structure, each layer of the multiple-layer structure comprising one of TiN, TaN, carbon, polysilicon, metal, metal compounds, and silicide. For example, as shown in FIG. 4, the first electrode structure 430 includes a first conductive layer 433 in contact with the capacitor dielectric layer 440 and the SN contact 470 directly, and a second conductive layer 435 surrounded by first conductive layer 433. The second electrode structure 450 includes a third conductive layer 453 in contact with the capacitor dielectric layer 440 directly, and a fourth conductive layer 455. In some implementations, the material of each layer of the multiple-layer structure is different from the material of other layers. For example, the first conductive layer 433 and the third conductive layer 453 are TiN, the second conductive layer 435 is polysilicon, and the fourth conductive layer 455 is GeSi. In some implementations, capacitor dielectric layer 440 includes dielectric materials, such as silicon oxide, silicon nitride, or high-k dielectrics including, but not limited to, Al₂O₃, HfO₂, Ta₂O₅, ZrO₂, TiO₂, or any combination thereof.

As shown in FIG. 4, in some implementations, the first electrode structure 430 includes a first uneven sidewall along the vertical direction (i.e., z-direction) and facing the second electrode structure 450. In some implementations, the second electrode structure 450 includes a second uneven sidewall along the vertical direction (i.e., z-direction) and facing the first electrode structure 430. In some implementations, the capacitor dielectric layer 440 includes sidewalls along the vertical direction (i.e., z-direction) and facing the first electrode structure 430 and the second electrode structure 450, respectively. In some implementations, the capacitor dielectric layer 440 can have an uneven thickness between the first electrode structure 430 and the second electrode structure 450. In some implementations, the first uneven sidewall of the first electrode structure 430, the second uneven sidewall of the second electrode structure 450, and/or the uneven sidewalls of the capacitor dielectric layer 440 can have randomly undulating surfaces. In some implementations, at least one of the first uneven sidewalls of the first electrode structure 430, and the second uneven sidewall of the second electrode structure 450 can include implanted ions with a randomly distributed concentration.

In some implementations, capacitors 420 have a relatively large height in the vertical direction (i.e., z-direction). Thus, the number of waves of the uneven sidewalls of the first electrode structure 430 and the second electrode structure 450 can be relatively large. Therefore, the surface area between the first electrode structure 430 and the second electrode structure 450 can be effectively increased within a same height of the capacitors 420, thereby increasing capacitance without altering the height or k-value, ultimately bolstering the sense margin. It is noted that such a structure requires mechanical stabilization with one or more mesh layers 486, as shown in FIG. 4. As such, the spacing between capacitors 420 remains consistent, thereby preventing capacitor corruption. Without mesh layers 486, the capacitors 420 might lean over and come in to contact with adjacent capacitors 420. Mesh layer 486 can include any suitable dielectric materials with a Mohs scale larger than that of silicon oxide, which has a Mohs scale of around six. In some implementations, mesh layers 486 can include silicon nitride, silicon carbide, corundum, boron carbide, boron nitride, or any combination thereof. In some implementations, as the aspect ratio of the capacitors 420 varies, the number of levels of mesh layers 486 can be adjusted accordingly to ensure mechanical stability.

In some implementations, the mesh layers 486 can laterally penetrate through the capacitor dielectric layer 440 and be in direct contact with the first electrode structure 430. In such implementations, the sidewalls of the first electrode structure 430 and the second electrode structure 450 that face to the mesh layers 486 can be even surfaces, while the sidewalls of the first electrode structure 430 and the second electrode structure 450 that opposite to the mesh layers 486 can be randomly undulating surfaces, as shown in FIG. 4.

In some implementations, one or more peripheral circuits (not shown) can be coupled to the vertical transistors 410 and the capacitors 420 through any other suitable conductive wirings. It is noted that the one or more peripheral circuits can include any suitable circuits for facilitating the operations of vertical transistors 410 and the capacitors 420 by applying voltage signals and/or current signals to and from the vertical transistors 410 and the capacitors 420. The one or more peripheral circuits can include various types of peripheral circuits formed using CMOS technologies.

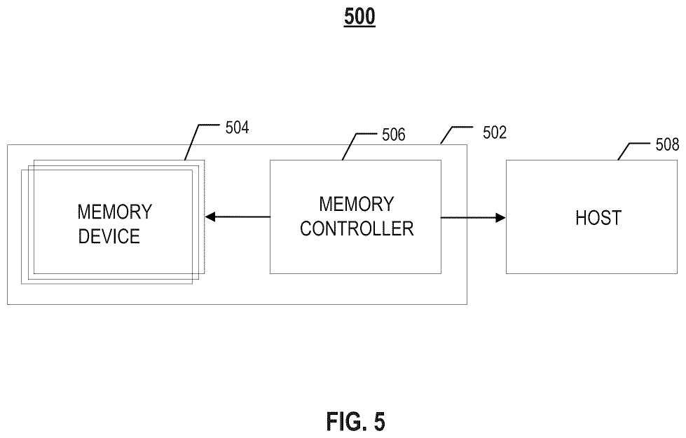

FIG. 5 illustrates a block diagram of a system 500 having a memory device, according to some implementations of the present disclosure. System 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, system 500 can include a host 508 and a memory system 502 having one or more memory devices 504 and a memory controller 506. Host 508 can be a processor of an electronic device, such as a central processing unit (CPU), or a system-on-chip (SoC), such as an application processor (AP). Host 508 can be configured to send or receive the data to or from memory devices 504. Memory device 504 can be any memory device disclosed herein, such as semiconductor device 100. In some implementations, memory device 504 can include one or more of the semiconductor structures 200/300/400 shown in FIGS. 2-4, respectively, each including vertical transistors and vertical capacitors, as described above in detail.

Memory controller 506 is coupled to memory device 504 and host 508 and is configured to control memory device 504, according to some implementations. Memory controller 506 can manage the data stored in memory device 504 and communicate with host 508. Memory controller 506 can be configured to control operations of memory device 504, such as read, write, and refresh operations. Memory controller 506 can also be configured to manage various functions with respect to the data stored or to be stored in memory device 504 including, but not limited to refresh and timing control, command/request translation, buffer and schedule, and power management. In some implementations, memory controller 506 is further configured to determine the maximum memory capacity that the computer system can use, the number of memory banks, memory type and speed, memory particle data depth and data width, and other important parameters. Any other suitable functions may be performed by memory controller 506 as well. Memory controller 506 can communicate with an external device (e.g., host 508) according to a particular communication protocol. For example, memory controller 506 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

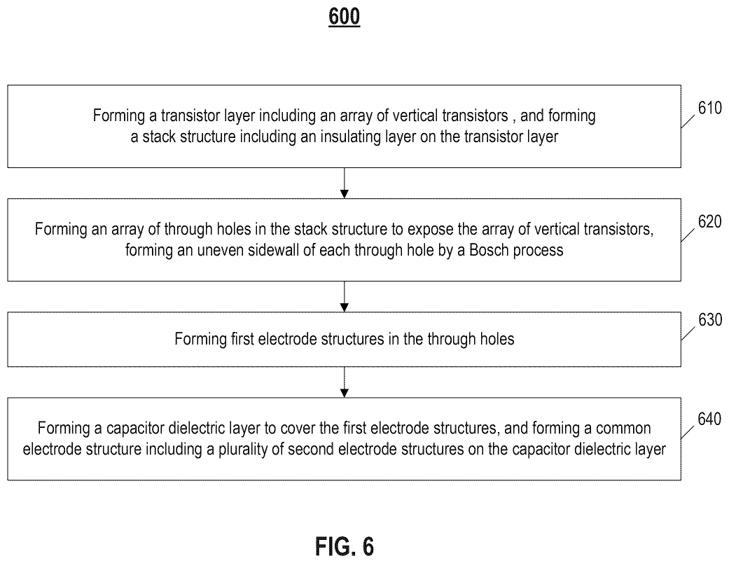

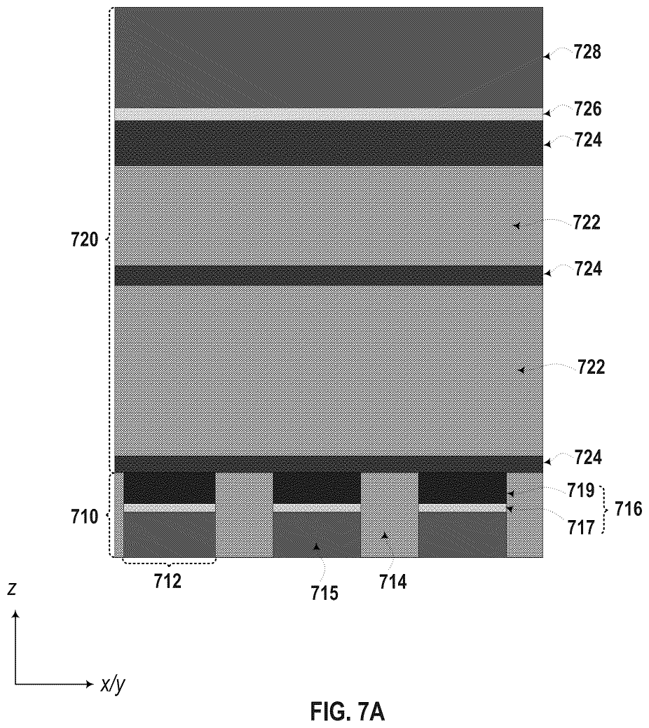

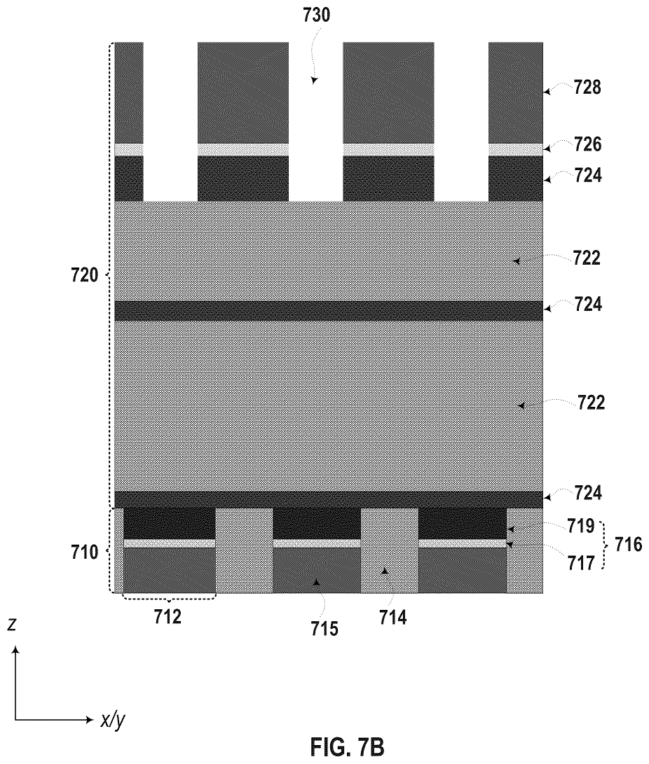

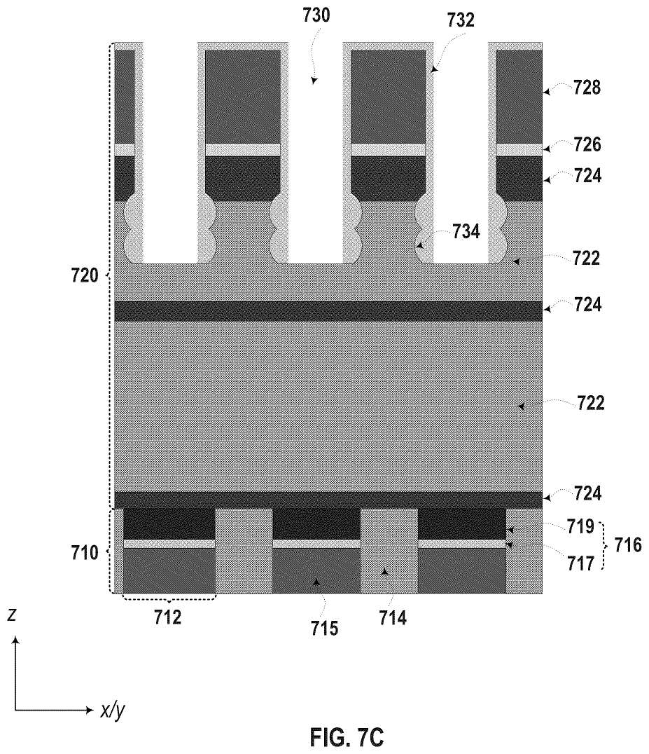

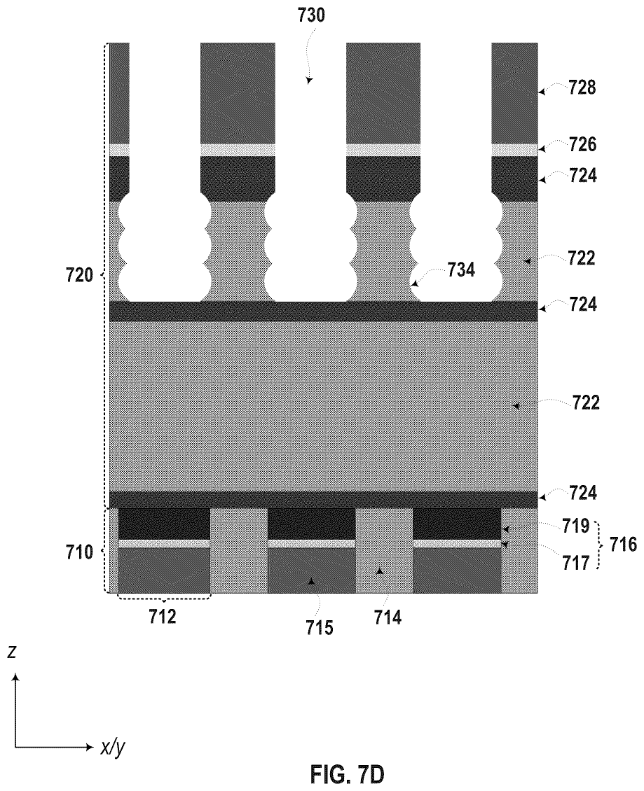

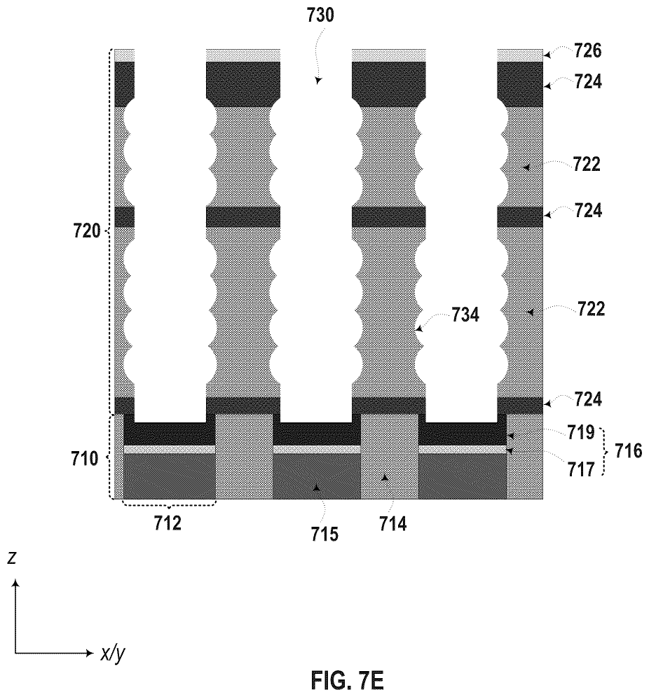

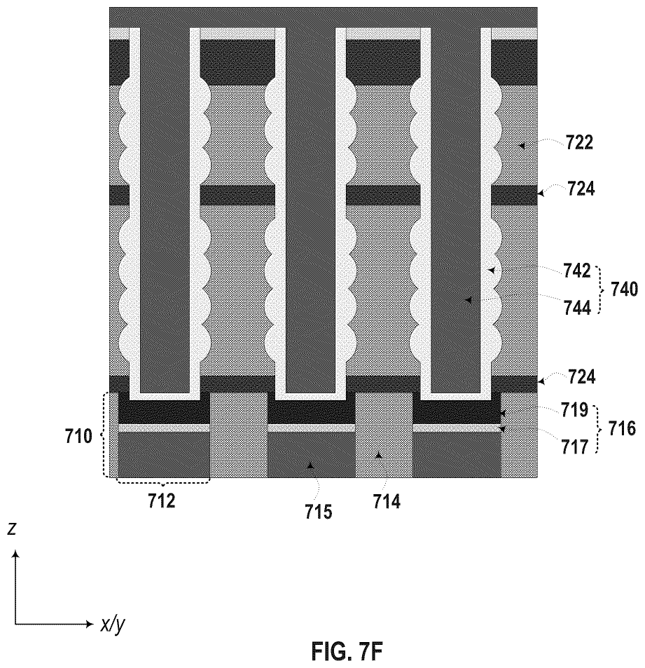

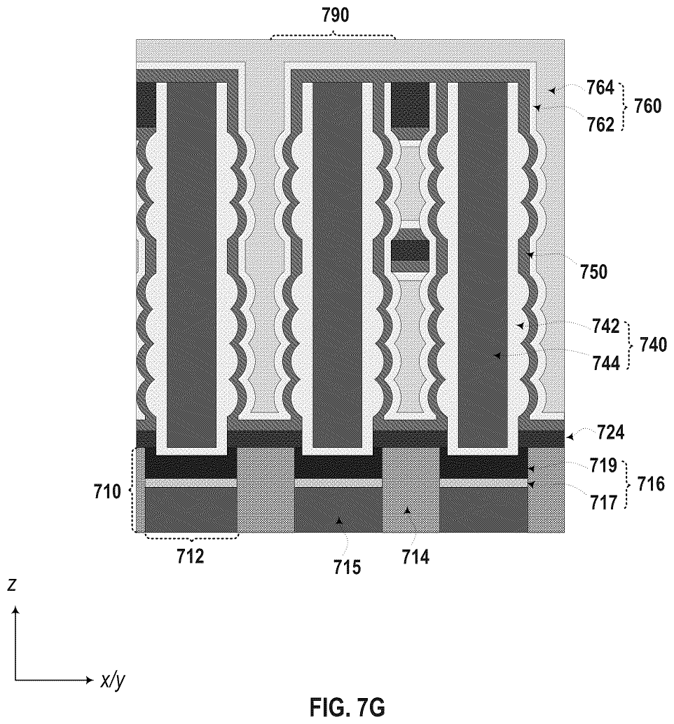

FIG. 6 illustrates a flowchart of a fabricating method 600 for forming a 3D memory device including vertical transistors and vertical capacitors, such as the semiconductor structure 200 described above in connection with FIG. 2, according to some implementations of the present disclosure. FIGS. 7A-7G illustrate schematic side cross-sectional views of a semiconductor structure at certain fabricating stages of the method 600 shown in FIG. 6, according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIG. 6, method 600 can start at operation 610, in which a transistor layer including an array of vertical transistors can be formed, and a stack structure including an insulating layer can be formed on the transistor layer. FIG. 7A illustrates a schematic side cross-sectional view of the 3D semiconductor structure in x/y-z plane after operation 610 of method 600.

As shown in FIG. 7A, a transistor layer 710 including an array of vertical transistors 712 can be formed. In some implementations, forming the transistor layer 710 can be referred to the fabricating methods disclosed in U.S. patent applicant Ser. No. 17/553,759, filed on Dec. 16, 2021, which is hereby incorporated by reference in its entirety.

In some implementations, forming the transistor layer 710 includes forming a plurality of semiconductor layers 715 each extending vertically in the z-direction. In some implementations, semiconductor layers 715 are used as the active region in which multiple channels can form for the array of vertical transistors 712. In some implementations, adjacent semiconductor layer 715 of neighboring vertical transistors 712 can be separated from each other by dielectric spacer 714. In some implementations, semiconductor layers 715 can be formed by patterning a semiconductor substrate including any suitable semiconductor material or metal oxide semiconductor material. In some implementations, forming the transistor layer 710 further includes doping the two ends (the upper end and lower end) of each semiconductor layer 715 with N-type dopants (e.g., P or As) or P-type dopants (e.g., B or Ga) at a desired doping level to form a source and a drain of each vertical transistor 712. It is noted that FIG. 7A only illustrates the source ends of semiconductor layers 715, while other portions of semiconductor layers 715 are omitted for simplicity.

In some implementations, forming the transistor layer 710 further includes forming a gate structure of each vertical transistor 712, including forming a gate dielectric (not shown) and a gate electrode (not shown). In some implementations, the gate dielectric can be formed by using dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the gate electrode can be formed by using conductive materials including, but not limited to, W, Co, Cu, Al, TiN, TaN, polysilicon, silicide, or any combination thereof. In some implementations, the gate electrode can be formed to include multiple conductive layers, such as a W layer over a TiN layer. In one example, the gate structure may be a “gate oxide/gate poly” gate in which the gate dielectric includes silicon oxide, and the gate electrode includes doped polysilicon. In another example, the gate structure may be a high-k metal gate (HKMG) in which the gate dielectric includes a high-k dielectric, and the gate electrode includes a metal. It is understood that the gate structure can be formed on one or more lateral sides of the semiconductor layer 715, such that the formed vertical transistors 712 can be single-gate transistors, double-gate transistors, or gate-all-around transistors.

In some implementations, forming the transistor layer 710 further includes forming SN contacts 716 coupled to source ends of the vertical transistors 712. In some implementations, forming the SN contacts 716 can include depositing different conductive materials to form a multi-layer conductive structure, such as a silicide layer (e.g., CoSi) 717 and a metal layer (e.g., W) 719 as shown in FIG. 7A.

In some implementations, a stack structure 720 can be formed on the transistor layer 710. In some implementations, the stack structure 720 can include one or more insulating layers stacked in the vertical direction (i.e., z-direction), such as one or more sacrificial layers 722 and one or more mesh layers 724, as shown in FIG. 7A. In some implementations, the one or more sacrificial layers 722 can include any suitable sacrificial material (e.g., silicon oxide, etc.), and the one or more mesh layers 724 can include any suitable dielectric material with a relatively higher Mohs scale (e.g., SiCN, SiBN, etc.). In some implementations, the stack structure 720 can further include one or more semiconductor layers, such as a first semiconductor layer 726 and a second semiconductor layer 728, on the insulating layers. In some implementations, the first semiconductor layer 726 and the second semiconductor layer 728 can have different semiconductor materials. For example, the first semiconductor layer 726 can include GeSi, and the second semiconductor layer 728 can include polysilicon. The one or more sacrificial layers 722, one or more mesh layers 724, and semiconductor layers 726 and 728, can be formed by a plurality of deposition processes (e.g., chemical vapor deposition (CVD), physical vapor deposition (PVD), atomic layer deposition (ALD), etc.).

Referring back to FIG. 6, method 600 can proceed to operation 620, in which an array of through holes can be formed in the stack structure to expose the array of vertical transistors, wherein each through hole has an uneven sidewall along the vertical direction. In some implementations, the array of through holes can each have a high aspect ratio, and be formed by using any suitable deep reactive ion etching (DRIE) process, such as a Bosch process. FIGS. 7B-7E illustrate schematic side cross-sectional views of the 3D semiconductor structure in x/y-z plane at different stages of operation 620 of method 600.

As shown in FIG. 7B, operation 620 can include forming an array of through holes 730 each penetrating the second semiconductor layer 728, the first semiconductor layer 726, and mesh layer 724 to expose sacrificial layer 722 (e.g., silicon oxide layer). It is noted that, each through hole 730 is aligned in the vertical direction to a corresponding SN contact 716 coupled with a respective vertical transistor 712.

As shown in FIGS. 7C-7E, operation 620 can include a cyclic etching process that involves alternating steps of etching and passivation. During the passivation step, a passivation layer 732 can be formed on the sidewall and a bottom surface of each through hole 730, as shown in FIG. 7C. In some implementations, the passivation layer 732 can be formed by depositing any suitable passivation material, such as silicon dioxide, silicon nitride, or various fluorocarbon-based polymers, on the sidewall and the bottom surface of the through holes 730. Then portions of the passivation material at the bottom surface of the through holes 730 can be removed to expose the sacrificial layer 722. The passivation layer 732 can act as a protective barrier, preventing further etching of the sidewalls of through holes 730 during subsequent etching steps, which helps to maintain the desired etch profile and improve the anisotropy of the etched features.

During the etching step, a portion of the sacrificial layer 722 (e.g., silicon oxide layer) can be removed to increase the depth of each through hole 730. In some implementations, plasma containing chemically reactive ions can be used to selectively etch away the sacrificial material from the sacrificial layer 722. The etching time can be controlled, such that the depth of each through hole 730 can be increased to a predetermined value. As shown in FIG. 7D, the formed sidewall 734 of the through holes 730 can have periodic, concave features, such as a wave shape or a scalloping shape.

The periodic, concave features of sidewall 734 of the through holes 730 are formed due to the isotropic etching in the sacrificial layer 722. During the isotropic etching, ions bombard the surface of the sacrificial layer 722 from various angles, leading to uneven material removal along the sidewalls of the through holes 730 and the formation of waves or scallops. Further, the passivation layer 732 on the sidewall of the through holes 730 can exacerbate sidewall waving or scalloping. While the passivation layer 732 helps protect the sidewalls of the through holes 730 from over-etching, it can also create a mask-like effect, leading to uneven material removal and the formation of waves or scallops.

Adjusting etching parameters such as gas flow rates, pressure, and power can influence the degree of sidewall waving or scalloping. In some implementations, a lateral difference between a peak position and a trough position of the waved surface of the uneven sidewall of the sacrificial layer 722 is in a range between about 10 nm and about 15 nm, and a vertical difference between adjacent two peak positions of the waved surface of the uneven sidewall of the sacrificial layer 722 is in a range between about 10 nm and about 30 nm.

The alternating steps of etching and passivation can be repeated as a cyclic etching process to periodically remove a portion of the sacrificial layer 722. As such, the depth of the through holes 730 can be increased, unit the through holes 730 exposes the SN contacts 716 or the vertical transistors 712, as shown in FIG. 7E. It is noted that, during the Bosch process, any other suitable etching process can be performed to remove portions of the one or more mesh layers 724, such that the through holes can vertically penetrate the entire stack structure 720. The remaining portions of the one or more mesh layers 724 can form a mesh structure to ensure mechanical stability.

Referring back to FIG. 6, method 600 can proceed to operation 630, in which first electrode structures can be formed in the through holes. In some implementations, each first electrode structure can include a multiple-layer structure and can be coupled with a corresponding vertical transistor. In some implementations, each first electrode structure can have a first uneven sidewall in contact with the sacrificial layer. FIG. 7F illustrates a schematic side cross-sectional view of the 3D semiconductor structure in x/y-z plane after operation 630 of method 600.

As shown in FIG. 7F, a first electrode structure 740 can be formed in each through hole 730. In some implementations, the first electrode structure 740 can include conductive materials including, but not limited to, W, Co, Cu, Al, TiN, TaN, polysilicon, silicide, or any combination thereof. In some implementations, the first electrode structure 740 can include a multiple-layer structure, each layer of the multiple-layer structure comprising one of TiN, TaN, carbon, polysilicon, metal, metal compounds, and silicide. For example, as shown in FIG. 7F, the first electrode structure 740 includes a first conductive layer 742 in contact with the SN contact 716 directly, and a second conductive layer 744 surrounded by first conductive layer 742. In some implementations, the material of each layer of the multiple-layer structure is different from the material of other layers. For example, the first conductive layer 742 includes TiN, and the second conductive layer 744 includes polysilicon. In some implementations, the first electrode structure 740 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.).

Referring back to FIG. 6, method 600 can proceed to operation 640, in which the sacrificial layer can be removed, a capacitor dielectric layer can be formed to cover the first electrode structures, and a common electrode structure including a plurality of second electrode structures can be formed. Each of the plurality of second electrode structures and a corresponding one of the first electrode structures form a vertical capacitor coupled with the corresponding one of the array of vertical transistors. FIG. 7G illustrates a schematic side cross-sectional view of the 3D semiconductor structure in x/y-z plane after operation 640 of method 600.

In some implementations, the sacrificial layers 722 shown in FIG. 7F can be removed by a selective etching process, such as wet etching, to form openings that expose the first electrode structures 740. A capacitor dielectric layer 750 can be formed to cover the first electrode structures 740 and the mesh layers 724. In some implementations, the capacitor dielectric layer 750 includes dielectric materials, such as silicon oxide, silicon nitride, or high-k dielectrics including, but not limited to, Al₂O₃, HfO₂, Ta₂O₅, ZrO₂, TiO₂, or any combination thereof. As shown in FIG. 7G, second electrode structures 760 can be formed on the capacitor dielectric layer 750 in the openings. In some implementations, the first electrode structures 740, the capacitor dielectric layer 750, and the second electrode structures 760 can form a vertical capacitor 790 coupled with a corresponding vertical transistor 712 through a corresponding SN contact 716. In some implementations, the second electrode structures 760 can be coupled with each other to form a common second electrode of vertical capacitors 790.

In some implementations, the second electrode structure 760 can include conductive materials including, but not limited to, W, Co, Cu, Al, TiN, TaN, polysilicon, silicide, or any combination thereof. In some implementations, the second electrode structure 760 can include a multiple-layer structure, each layer of the multiple-layer structure comprising one of TiN, TaN, carbon, polysilicon, metal, metal compounds, and silicide. For example, as shown in FIG. 7G, the second electrode structure 760 includes a third conductive layer 762 in contact with the capacitor dielectric layer 750 directly, and a fourth conductive layer 764 on the third conductive layer 762. In some implementations, the material of each layer of the multiple-layer structure is different from the material of other layers. For example, the third conductive layer 762 includes TiN, and the fourth conductive layer 764 includes GeSi. In some implementations, the capacitor dielectric layer 750 and the second electrode structures 760 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.).

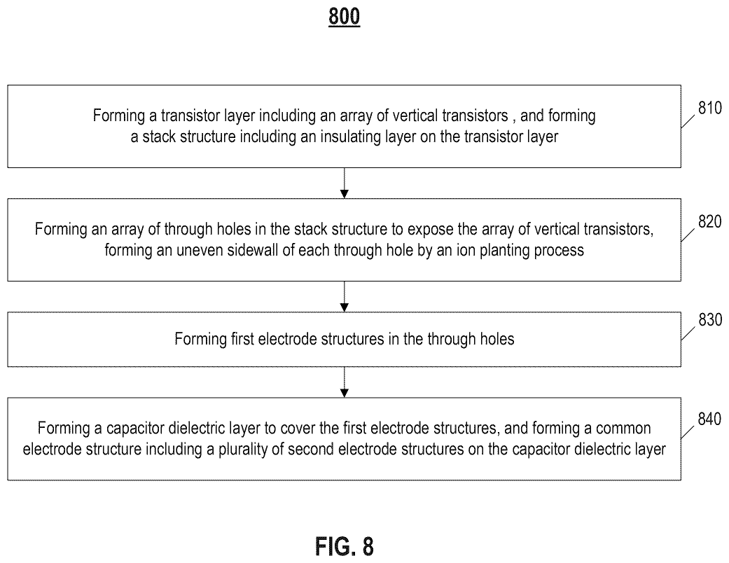

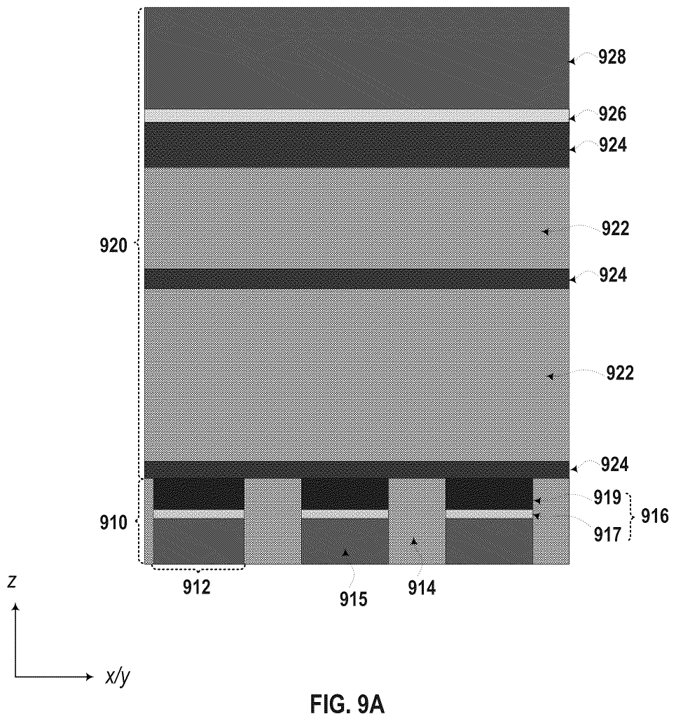

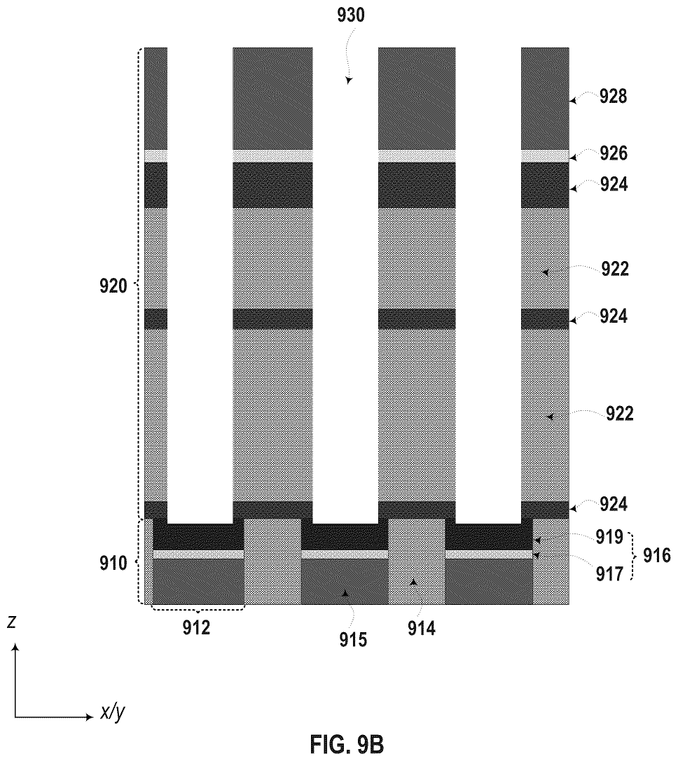

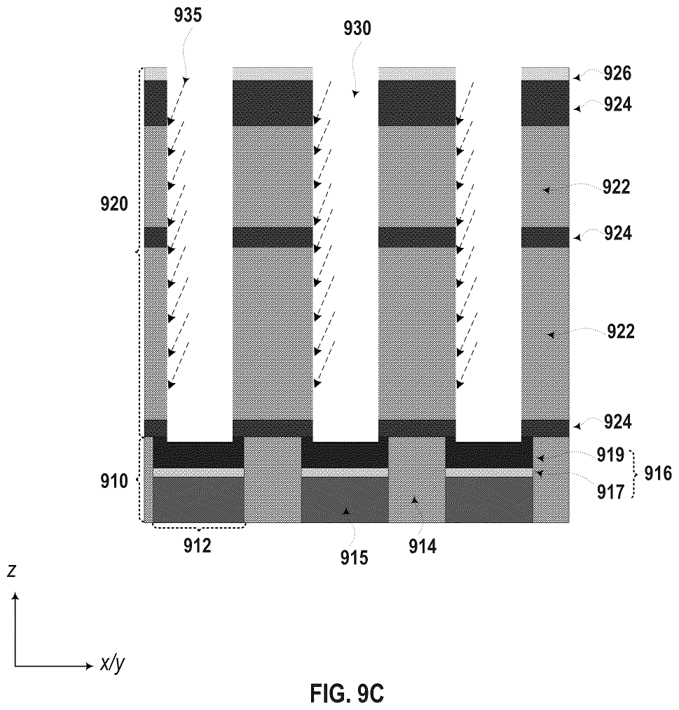

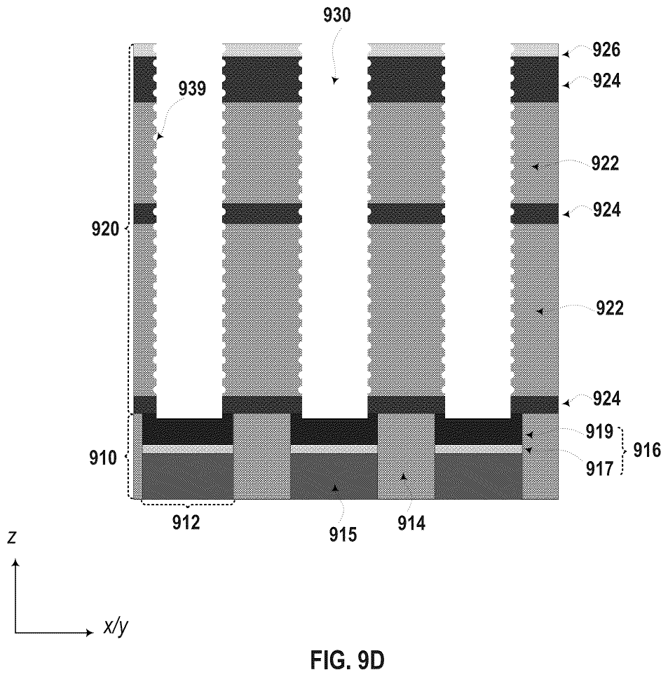

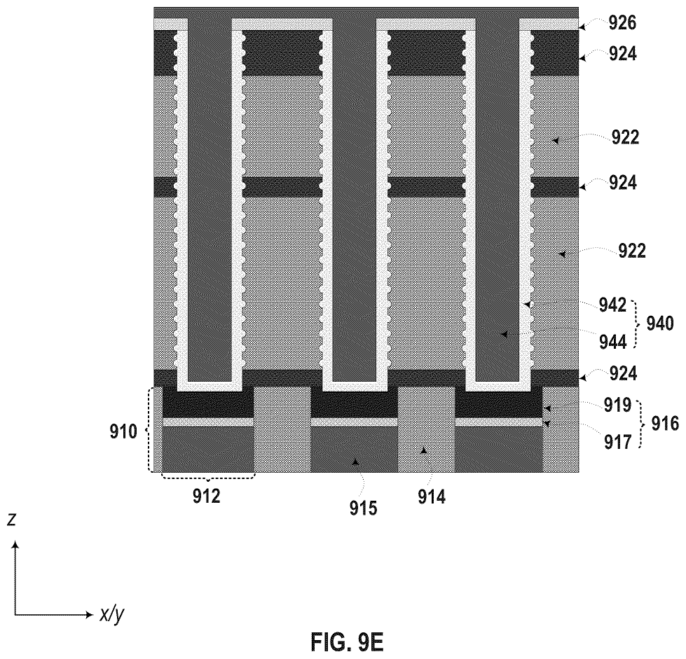

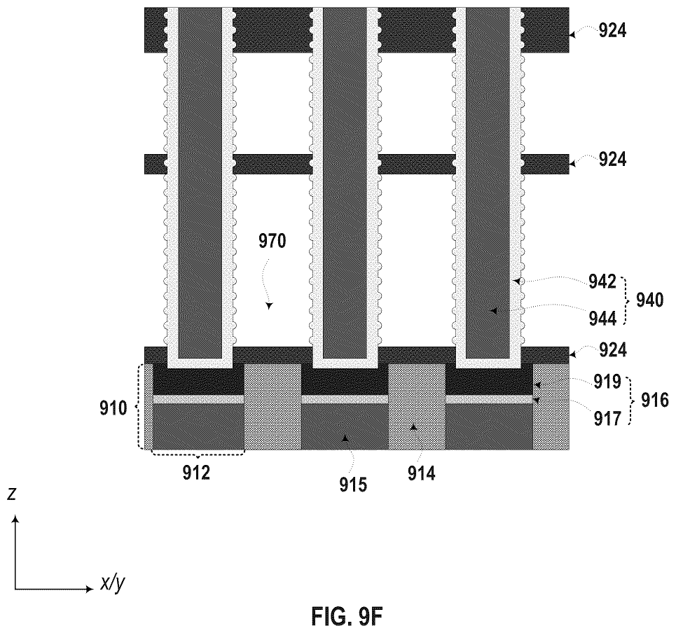

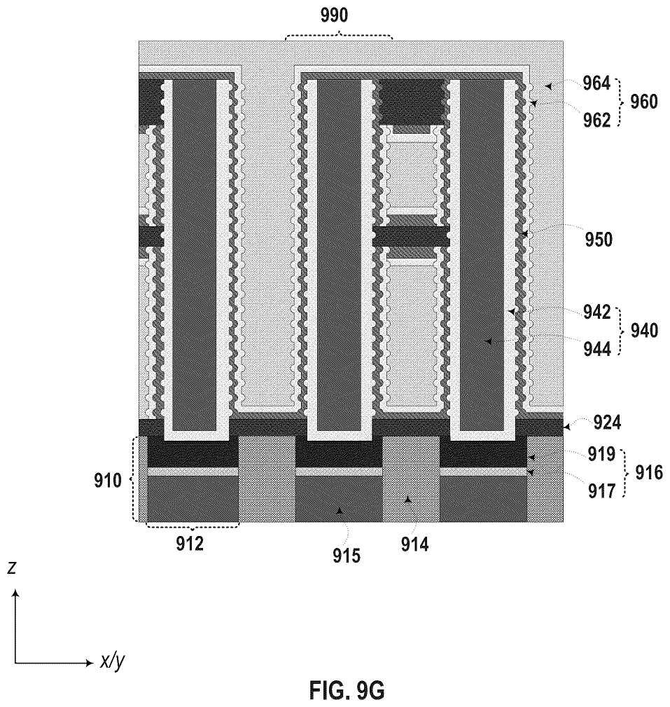

FIG. 8 illustrates a flowchart of a fabricating method 800 for forming a 3D memory device including vertical transistors and vertical capacitors, such as the semiconductor structure 300 described above in connection with FIG. 3, according to some implementations of the present disclosure. FIGS. 9A-9G illustrate schematic side cross-sectional views of a semiconductor structure at certain fabricating stages of method 800 shown in FIG. 8, according to various implementations of the present disclosure. It is understood that the operations shown in method 800 are not exhaustive and that other operations can be performed as well before, after, or between any of the illustrated operations. Further, some of the operations may be performed simultaneously, or in a different order than shown in FIG. 8.

As shown in FIG. 8, method 800 can start at operation 810, in which a transistor layer including an array of vertical transistors can be formed, and a stack structure including an insulating layer can be formed on the transistor layer. FIG. 9A illustrates a schematic side cross-sectional view of the 3D semiconductor structure in x/y-z plane after operation 810 of method 800.

As shown in FIG. 9A, a transistor layer 910 including an array of vertical transistors 912 can be formed. In some implementations, forming the transistor layer 910 includes forming a plurality of semiconductor layers 915 each extending vertically in the z-direction. In some implementations, the semiconductor layers 915 are used as the active region in which multiple channels can form for the array of vertical transistors 912. In some implementations, adjacent semiconductor layer 915 of neighboring vertical transistors 912 can be separated from each other by dielectric spacer 914. In some implementations, semiconductor layers 915 can be formed by patterning a semiconductor substrate including any suitable semiconductor material or metal oxide semiconductor material. In some implementations, forming the transistor layer 910 further includes doping the two ends (the upper end and lower end) of each semiconductor layer 915 with N-type dopants (e.g., P or As) or P-type dopants (e.g., B or Ga) at a desired doping level to form a source and a drain of each vertical transistor 912. It is noted that FIG. 9A only illustrates the source ends of semiconductor layers 915, while other portions of semiconductor layers 915 are omitted for simplicity.

In some implementations, forming the transistor layer 910 further includes forming a gate structure of each vertical transistor 912, including forming a gate dielectric (not shown) and a gate electrode (not shown). In some implementations, the gate dielectric can be formed by using dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the gate electrode can be formed by using conductive materials including, but not limited to, W, Co, Cu, Al, TiN, TaN, polysilicon, silicide, or any combination thereof. In some implementations, the gate electrode can be formed to include multiple conductive layers, such as a W layer over a TiN layer. In one example, the gate structure may be a “gate oxide/gate poly” gate in which the gate dielectric includes silicon oxide, and the gate electrode includes doped polysilicon. In another example, the gate structure may be a high-k metal gate (HKMG) in which the gate dielectric includes a high-k dielectric and gate electrode includes a metal. It is understood that the gate structure can be formed on one or more lateral sides of the semiconductor layer 915, such that the formed vertical transistors 912 can be single-gate transistors, double-gate transistors, or gate-all-around transistors.

In some implementations, forming the transistor layer 910 further includes forming SN contacts 916 coupled to source ends of the vertical transistors 912. In some implementations, forming the SN contacts 916 can include depositing different conductive materials to form a multi-layer conductive structure, such as a silicide layer (e.g., CoSi) 917 and a metal layer (e.g., W) 919 as shown in FIG. 9A.

In some implementations, a stack structure 920 can be formed on the transistor layer 910. In some implementations, the stack structure 920 can include one or more insulating layers stacked in the vertical direction (i.e., z-direction), such as one or more sacrificial layers 922 and one or more mesh layers 924, as shown in FIG. 9A. In some implementations, the one or more sacrificial layers 922 can include any suitable sacrificial material (e.g., silicon oxide, etc.), and the one or more mesh layers 924 can include any suitable dielectric material with a relatively higher Mohs scale (e.g., SiCN, SiBN, etc.). In some implementations, the stack structure 920 can further include one or more semiconductor layers, such as a first semiconductor layer 926 and a second semiconductor layer 928, on the insulating layers. In some implementations, the first semiconductor layer 926 and the second semiconductor layer 928 can have different semiconductor materials. For example, the first semiconductor layer 926 can include GeSi, and the second semiconductor layer 928 can include polysilicon. The one or more sacrificial layers 922, one or more mesh layers 924, and semiconductor layers 926 and 928, can be formed by a plurality of deposition processes (e.g., chemical vapor deposition (CVD), physical vapor deposition (PVD), atomic layer deposition (ALD), etc.).

Referring back to FIG. 8, method 800 can proceed to operation 820, in which an array of through holes can be formed in the stack structure to expose the array of vertical transistors, wherein each through hole has an uneven sidewall along the vertical direction. In some implementations, the array of through holes can each have a high aspect ratio, and be formed by using any suitable deep reactive ion etching (DRIE) process and ion implanting process. FIGS. 9B-9D illustrate schematic side cross-sectional views of the 3D semiconductor structure in x/y-z plane at different stages of operation 820 of method 800.

As shown in FIG. 9B, operation 820 can include forming an array of through holes 930 each penetrating the second semiconductor layer 928, the first semiconductor layer 926, the one or more mesh layers 924, and the one or more sacrificial layers 922 to expose the SN contacts 916, respectively. In some implementations, operation 820 can further include performing an ion implanting process to the sidewalls of the through holes 930. In some implementations, the ion implanting process can involve accelerating charged ions (e.g., B ions or P ions) 935 to high energies and bombarding them onto the sidewalls of the through holes 930, as shown in FIG. 9C. The ions 935 can penetrate the surface material of the sacrificial layers 922 and the mesh layers 924 and create defects or modify the material properties in a controlled manner. By adjusting the beam direction, the energy, and the dosage of the ions 935, the depth and distribution of the implanted ions within the sidewalls of the through holes 930 can be controlled. As such, uneven surfaces and non-uniform ion distributions can be created on the sidewalls of the through holes 930, as shown in FIG. 9D. It is noted that, although FIG. 9D shows that the sidewalls of the through holes 930 include a periodic waved shape, and the sidewalls of the through holes 930 can have a randomly undulating surface 939 with a randomly distributed implanted ion concentration. For example, the lateral differences between peak positions and trough positions of the randomly undulating surface of the uneven sidewalls of the through holes 930 can be in a range between about 2 nm and about 8 nm, and the vertical differences between adjacent peak positions and/or trough positions of the randomly undulating surface 939 of the uneven sidewalls of the through holes 930 can be randomly distributed.

Referring back to FIG. 8, method 800 can proceed to operation 830, in which first electrode structures can be formed in the through holes. In some implementations, each first electrode structure can include a multiple-layer structure and can be coupled with a corresponding vertical transistor. In some implementations, each first electrode structure can have a first uneven sidewall in contact with the sacrificial layer. FIG. 9E illustrates a schematic side cross-sectional view of the 3D semiconductor structure in x/y-z plane after operation 830 of method 800.

As shown in FIG. 9E, a first electrode structure 940 can be formed in each through hole 930. In some implementations, the first electrode structure 940 can include conductive materials including, but not limited to, W, Co, Cu, Al, TiN, TaN, polysilicon, silicide, or any combination thereof. In some implementations, the first electrode structure 940 can include a multiple-layer structure, each layer of the multiple-layer structure comprising one of TiN, TaN, carbon, polysilicon, metal, metal compounds, and silicide. For example, as shown in FIG. 9E, the first electrode structure 940 includes a first conductive layer 942 in contact with the SN contact 916 directly, and a second conductive layer 944 surrounded by first conductive layer 942. In some implementations, the material of each layer of the multiple-layer structure is different from the material of other layers. For example, the first conductive layer 942 includes TiN, and the second conductive layer 944 includes polysilicon. In some implementations, the first electrode structure 940 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.).

Referring back to FIG. 8, method 800 can proceed to operation 840, in which the sacrificial layer can be removed, a capacitor dielectric layer can be formed to cover the first electrode structures, and a common electrode structure including a plurality of second electrode structures can be formed. Each of the plurality of second electrode structures and a corresponding one of the first electrode structures form a vertical capacitor coupled with the corresponding one of the array of vertical transistors. FIGS. 9F-9G illustrate schematic side cross-sectional views of the 3D semiconductor structure in x/y-z plane at different stages of operation 840 of method 800.

In some implementations, sacrificial layers 922 shown in FIG. 9E can be removed by a selective etching process, such as wet etching, to form openings 970 that expose first electrode structures 940, as shown in FIG. 9F. A capacitor dielectric layer 950 can be formed to cover first electrode structures 940 and the mesh layers 924, as shown in FIG. 9G. In some implementations, the capacitor dielectric layer 950 includes dielectric materials, such as silicon oxide, silicon nitride, or high-k dielectrics including, but not limited to, Al₂O₃, HfO₂, Ta₂O₅, ZrO₂, TiO₂, or any combination thereof. As shown in FIG. 9G, second electrode structures 960 can be formed on the capacitor dielectric layer 950 in the openings. In some implementations, first electrode structures 940, the capacitor dielectric layer 950, and second electrode structures 960 can form a vertical capacitor 990 coupled with a corresponding vertical transistor 912 through a corresponding SN contact 916. In some implementations, the second electrode structures 960 can be coupled with each other to form a common second electrode of vertical capacitors 990.

In some implementations, the second electrode structure 960 can include conductive materials including, but not limited to, W, Co, Cu, Al, TiN, TaN, polysilicon, silicide, or any combination thereof. In some implementations, the second electrode structure 960 can include a multiple-layer structure, each layer of the multiple-layer structure comprising one of TiN, TaN, carbon, polysilicon, metal, metal compounds, and silicide. For example, as shown in FIG. 9G, the second electrode structure 960 includes a third conductive layer 962 in contact with the capacitor dielectric layer 950 directly, and a fourth conductive layer 964 on the third conductive layer 962. In some implementations, the material of each layer of the multiple-layer structure is different from the material of other layers. For example, the third conductive layer 962 includes TiN, and the fourth conductive layer 964 includes GeSi. In some implementations, the capacitor dielectric layer 950 and the second electrode structures 960 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.).

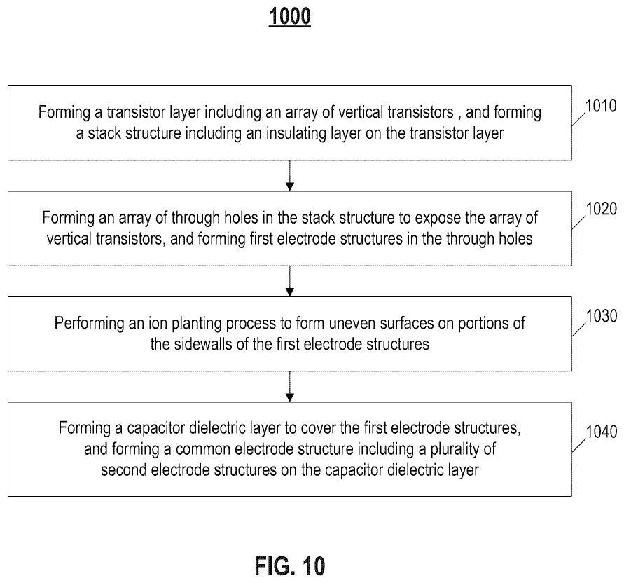

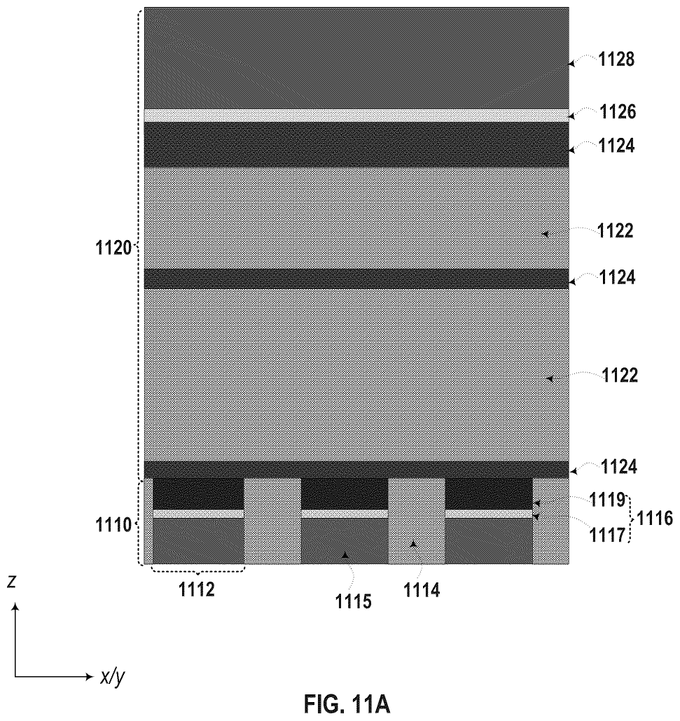

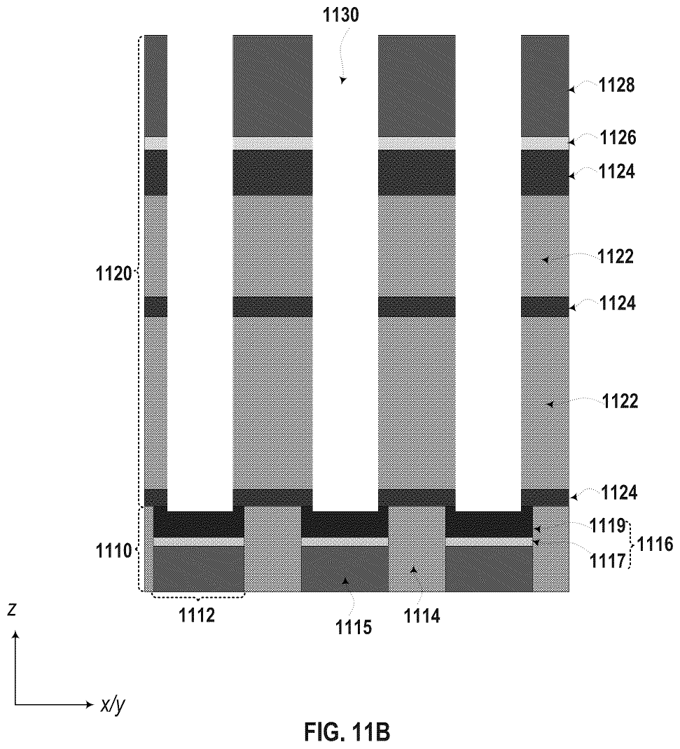

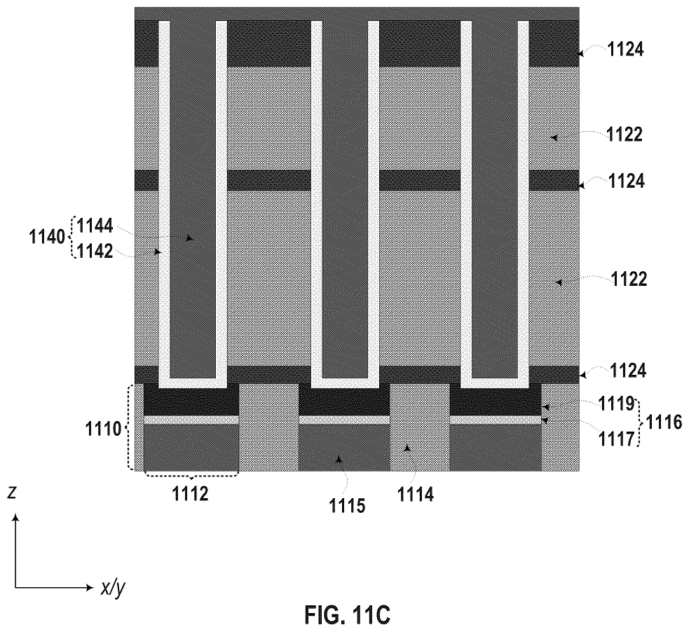

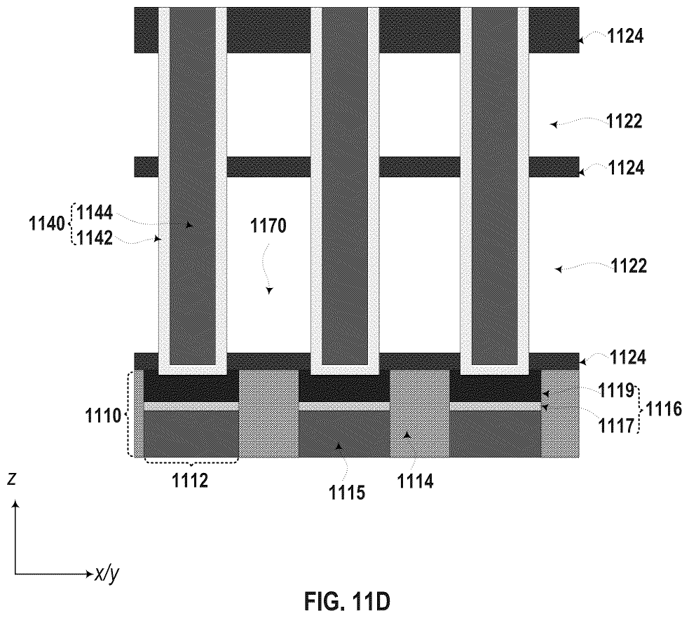

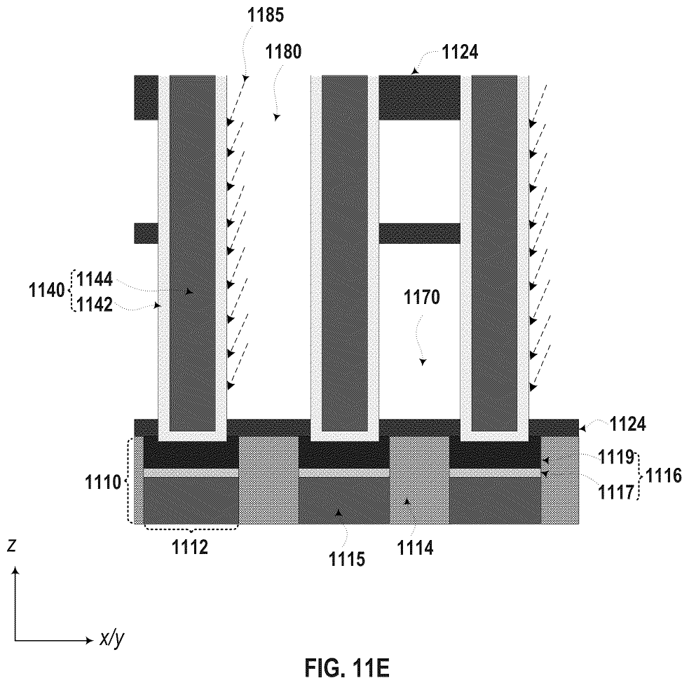

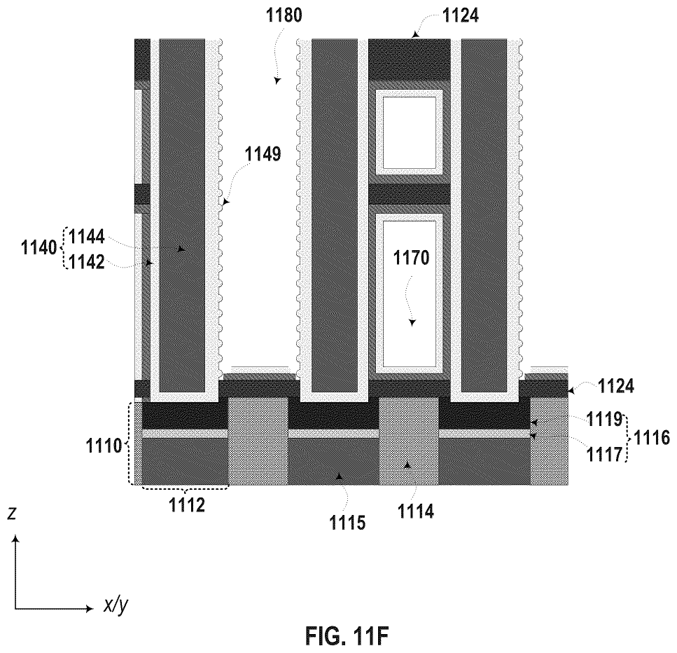

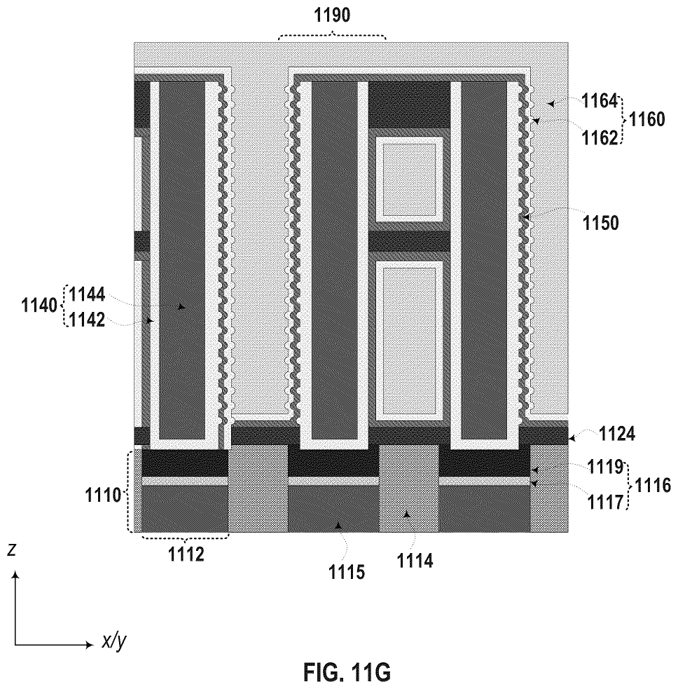

FIG. 10 illustrates a flowchart of a fabricating method 1000 for forming a 3D memory device including vertical transistors and vertical capacitors, such as the semiconductor structure 400 described above in connection with FIG. 4, according to some implementations of the present disclosure. FIGS. 11A-11G illustrate schematic side cross-sectional views of a semiconductor structure at certain fabricating stages of the method 1000 shown in FIG. 10, according to various implementations of the present disclosure. It is understood that the operations shown in method 1000 are not exhaustive and that other operations can be performed as well before, after, or between any of the illustrated operations. Further, some of the operations may be performed simultaneously, or in a different order than shown in FIG. 10.

As shown in FIG. 10, method 1000 can start at operation 1010, in which a transistor layer including an array of vertical transistors can be formed, and a stack structure including an insulating layer can be formed on the transistor layer. FIG. 11A illustrates a schematic side cross-sectional view of the 3D semiconductor structure in x/y-z plane after operation 1010 of method 1000.

As shown in FIG. 11A, a transistor layer 1110 including an array of vertical transistors 1112 can be formed. In some implementations, forming the transistor layer 1110 includes forming a plurality of semiconductor layers 1115 each extending vertically in the z-direction. In some implementations, the semiconductor layers 1115 are used as the active region in which multiple channels can form for the array of vertical transistors 1112. In some implementations, adjacent semiconductor layer 1115 of neighboring vertical transistors 1112 can be separated from each other by dielectric spacer 1114. In some implementations, semiconductor layers 1115 can be formed by patterning a semiconductor substrate including any suitable semiconductor material or metal oxide semiconductor material. In some implementations, forming the transistor layer 1110 further includes doping the two ends (the upper end and lower end) of each semiconductor layer 1115 with N-type dopants (e.g., P or As) or P-type dopants (e.g., B or Ga) at a desired doping level to form a source and a drain of each vertical transistor 1112. It is noted that FIG. 11A only illustrates the source ends of semiconductor layers 1115, while other portions of semiconductor layers 1115 are omitted for simplicity.

In some implementations, forming the transistor layer 1110 further includes forming a gate structure of each vertical transistor 1112, including forming a gate dielectric (not shown) and a gate electrode (not shown). In some implementations, the gate dielectric can be formed by using dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the gate electrode can be formed by using conductive materials including, but not limited to, W, Co, Cu, Al, TiN, TaN, polysilicon, silicide, or any combination thereof. In some implementations, the gate electrode can be formed to include multiple conductive layers, such as a W layer over a TiN layer. In one example, the gate structure may be a “gate oxide/gate poly” gate in which the gate dielectric includes silicon oxide, and the gate electrode includes doped polysilicon. In another example, the gate structure may be a high-k metal gate (HKMG) in which the gate dielectric includes a high-k dielectric, and the gate electrode includes a metal. It is understood that the gate structure can be formed on one or more lateral sides of the semiconductor layer 1115, such that the formed vertical transistors 1112 can be single-gate transistors, double-gate transistors, or gate-all-around transistors.

In some implementations, forming the transistor layer 1110 further includes forming SN contacts 1116 coupled to source ends of the vertical transistors 1112. In some implementations, forming the SN contacts 1116 can include depositing different conductive materials to form a multi-layer conductive structure, such as a silicide layer (e.g., CoSi) 1117 and a metal layer (e.g., W) 1119 as shown in FIG. 11A.

In some implementations, a stack structure 1120 can be formed on the transistor layer 1110. In some implementations, the stack structure 1120 can include one or more insulating layers stacked in the vertical direction (i.e., z-direction), such as one or more sacrificial layers 1122 and one or more mesh layers 1124, as shown in FIG. 11A. In some implementations, the one or more sacrificial layers 1122 can include any suitable sacrificial material (e.g., silicon oxide, etc.), and the one or more mesh layers 1124 can include any suitable dielectric material with a relatively higher Mohs scale (e.g., SiCN, SiBN, etc.). In some implementations, the stack structure 1120 can further include one or more semiconductor layers, such as a first semiconductor layer 1126 and a second semiconductor layer 1128, on the insulating layers. In some implementations, the first semiconductor layer 1126 and the second semiconductor layer 1128 can have different semiconductor materials. For example, the first semiconductor layer 1126 can include GeSi, and the second semiconductor layer 1128 can include polysilicon. The one or more sacrificial layers 1122, one or more mesh layers 1124, and semiconductor layers 1126 and 1128, can be formed by a plurality of deposition processes (e.g., chemical vapor deposition (CVD), physical vapor deposition (PVD), atomic layer deposition (ALD), etc.).

Referring back to FIG. 10, method 1000 can proceed to operation 1020, in which an array of through holes can be formed in the stack structure to expose the array of vertical transistors, and the first electrode structures can be formed in the through holes. In some implementations, the array of through holes can each have a high aspect ratio, and be formed by using any suitable deep reactive ion etching (DRIE) process. In some implementations, each first electrode structure can include a multiple-layer structure and can be coupled with a corresponding vertical transistor. FIG. 11B illustrates a schematic side cross-sectional view of the 3D semiconductor structure in x/y-z plane after operation 820 of method 800.

As shown in FIG. 11B, an array of through holes 1130 can be formed to penetrate the second semiconductor layer 1128, the first semiconductor layer 1126, the one or more mesh layers 1124, and the one or more sacrificial layers 1122 to expose the SN contacts 1116, respectively. As shown in FIG. 11C, first electrode structure 1140 can be formed in through holes 1130. In some implementations, first electrode structures 1140 can include conductive materials including, but not limited to, W, Co, Cu, Al, TiN, TaN, polysilicon, silicide, or any combination thereof. In some implementations, first electrode structure 1140 can include a multiple-layer structure, each layer of the multiple-layer structure comprising one of TiN, TaN, carbon, polysilicon, metal, metal compounds, and silicide. For example, as shown in FIG. 11C, first electrode structure 1140 includes a first conductive layer 1142 in contact with SN contact 1116 directly, and a second conductive layer 1144 surrounded by first conductive layer 1142. In some implementations, the material of each layer of the multiple-layer structure is different from the material of other layers. For example, first conductive layer 1142 includes TiN, and second conductive layer 1144 includes polysilicon. In some implementations, first electrode structure 1140 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.).

Referring back to FIG. 10, method 1000 can proceed to operation 1030, in which the sacrificial layers and portions of the mesh layers can be removed, and an ion planting process can be performed to form uneven surfaces on portions of the sidewalls of the first electrode structures. FIGS. 11D-11F illustrate schematic side cross-sectional views of the 3D semiconductor structure in x/y-z plane at different stages of operation 1030 of method 1000.

In some implementations, operation 1030 can include removing the sacrificial layers 1122 shown in FIG. 11C by a selective etching process, such as wet etching, to form first openings 1170 expose the sidewalls of first electrode structures 1140, as shown in FIG. 11D. In some implementations, operation 1030 can further include removing portions of the mesh layers 1124 by a selective etching process, such as wet etching, to form second openings 1180, such that portions of the exposed sidewalls of first electrode structures 1140 are not blocked by the mesh layers 1124, as shown in FIG. 11E.

In some implementations, operation 1030 can further include performing in ion implanting process through the second openings 1180 to portions of the sidewalls of first electrode structures 1140. In some implementations, the ion implanting process can involve accelerating charged ions (e.g., B ions or P ions) 1185 to high energies and bombarding them onto portions of the sidewalls of first electrode structures 1140, as shown in FIG. 11E. The ions 1185 can penetrate the surface material of first electrode structures 1140 and create defects or modify the material properties in a controlled manner. By adjusting the beam direction, the energy, and the dosage of the ions 1185, the depth and distribution of the implanted ions within the sidewalls of the first electrode structures 1140 can be controlled. As such, uneven surfaces and non-uniform ion distributions can be created on the sidewalls of first electrode structures 1140, as shown in FIG. 11F. It is noted that, although FIG. 11F shows that the sidewalls of first electrode structures 1140 include a periodic waved shape, and the sidewalls of first electrode structures 1140 can have a randomly undulating surface 1149 with a randomly distributed implanted ion concentration. For example, the lateral differences between peak positions and trough positions of the randomly undulating surface of the uneven sidewalls of first electrode structures 1140 can be in a range between about 2 nm and about 8 nm, and the vertical differences between adjacent peak positions and/or trough positions of the randomly undulating surface 1149 of the uneven sidewalls of first electrode structures 1140 can be randomly distributed.

Referring back to FIG. 10, method 1000 can proceed to operation 1040, in which a capacitor dielectric layer can be formed to cover the first electrode structures, and a common electrode structure including a plurality of second electrode structures on the capacitor dielectric layer. Each of the plurality of second electrode structures and a corresponding one of the of first electrode structures form a vertical capacitor coupled with the corresponding one of the array of vertical transistors. FIG. 11G illustrates a schematic side cross-sectional view of the 3D semiconductor structure in x/y-z plane after operation 1040 of method 1000.

In some implementations, a capacitor dielectric layer 1150 can be formed to cover first electrode structures 1140 and the mesh layers 1124, as shown in FIG. 11G. In some implementations, the capacitor dielectric layer 1150 includes dielectric materials, such as silicon oxide, silicon nitride, or high-k dielectrics including, but not limited to, Al₂O₃, HfO₂, Ta₂O₅, ZrO₂, TiO₂, or any combination thereof. As shown in FIG. 11G, second electrode structures 1160 can be formed on the capacitor dielectric layer 1150 in the openings. In some implementations, first electrode structures 1140, capacitor dielectric layer 1150, and second electrode structures 1160 can form a vertical capacitor 1190 coupled with a corresponding vertical transistor 1112 through a corresponding SN contact 1116. In some implementations, the second electrode structures 1160 can be coupled with each other to form a common second electrode of vertical capacitors 1190.

In some implementations, the second electrode structure 1160 can include conductive materials including, but not limited to, W, Co, Cu, Al, TiN, TaN, polysilicon, silicide, or any combination thereof. In some implementations, the second electrode structure 1160 can include a multiple-layer structure, each layer of the multiple-layer structure comprising one of TiN, TaN, carbon, polysilicon, metal, metal compounds, and silicide. For example, as shown in FIG. 11G, the second electrode structure 1160 includes a third conductive layer 1162 in contact with the capacitor dielectric layer 1150 directly, and a fourth conductive layer 1164 on the third conductive layer 1162. In some implementations, the material of each layer of the multiple-layer structure is different from the material of other layers. For example, the third conductive layer 1162 includes TiN, and the fourth conductive layer 1164 includes GeSi. In some implementations, the capacitor dielectric layer 1150 and the second electrode structures 1160 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.).

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations, but should be defined only in accordance with the following claims and their equivalents.

What is claimed is:

1. A semiconductor device, comprising:
an array of vertical transistors; and
an array of vertical capacitors each comprising:
a first electrode structure coupled with a corresponding one of the array of vertical transistors, and
a second electrode structure electrically isolated from the first electrode structure,
wherein the first electrode structure has a first uneven sidewall along a vertical direction and facing the second electrode structure.

2. The semiconductor device of claim 1, wherein each capacitor further comprises:
a capacitor dielectric layer having an uneven thickness between the first electrode structure and the second electrode structure.

3. The semiconductor device of claim 1, wherein:
the second electrode structures of the array of vertical capacitors are connected with each other to form a common electrode.

4. The semiconductor device of claim 1, wherein:
the second electrode structure has a second uneven sidewall facing the first electrode structure.

5. The semiconductor device of claim 1, further comprising:
a mesh structure in between adjacent vertical capacitors of the array of vertical capacitors,
wherein the first electrode structure has a smooth sidewall facing the mesh structure.

6. The semiconductor device of claim 1, further comprising:
a mesh structure in between adjacent vertical capacitors of the array of vertical capacitors,
wherein a portion of the first electrode structure in contact with the mesh structure has a smooth sidewall.

7. The semiconductor device of claim 1, wherein the first uneven sidewall has a waved surface.

8. The semiconductor device of claim 7, wherein:
a lateral difference between a peak position and a trough position of the waved surface of the first uneven sidewall is in a range between about 10 nm and about 15 nm; and
a vertical difference between adjacent two peak positions of the waved surface of the first uneven sidewall is in a range between about 10 nm and about 30 nm.

9. The semiconductor device of claim 1, wherein:
the first uneven sidewall has a randomly undulating surface or includes implanted ions with a randomly distributed concentration.

10. The semiconductor device of claim 9, wherein:
a lateral difference between a peak position and a trough position of the randomly undulating surface of the first uneven sidewall is in a range between about 2 nm and about 8 nm; and
the implanted ions are phosphorus ions or boron ions.

11. A method of forming a semiconductor device, comprising:
forming an array of vertical transistors; and
forming an array of first electrode structures each extending along a vertical direction and coupled with a corresponding one of the array of vertical transistors, wherein each first electrode structure has a first uneven sidewall;
forming a capacitor dielectric layer to cover the array of first electrode structures; and
forming a common electrode structure including a plurality of second electrode structures, wherein each of the plurality of second electrode structures and a corresponding one of the array of first electrode structures form a vertical capacitor coupled with the corresponding one of the array of vertical transistors.

12. The method of claim 11, wherein forming the array of first electrode structures comprises:
forming an insulating layer on the array of vertical transistors;
forming an array of through holes in the insulating layer to expose the array of vertical transistors, wherein each through hole has an uneven sidewall along the vertical direction; and
depositing one or more conductive materials into the array of through holes to form the array of first electrode structures.

13. The method of claim 12, wherein forming an array of through holes comprises:
performing a plurality of cycles of etching processes, each cycle of etching process comprising:
removing a portion of the insulating layer to increase a depth of each through hole;
forming a passivating layer on a sidewall and a bottom surface of each through hole; and
removing a portion of the passivating layer on the bottom surface of each through hole.

14. The method of claim 12, wherein forming an array of through holes comprises:
performing an ion implanting process to sidewalls of the array of through holes, such that each through hole has the uneven sidewall.

15. The method of claim 14, wherein performing the ion implanting process comprises:
implanting phosphorus ions or boron ions to the sidewalls of the array of through holes.

16. The method of claim 11, wherein forming the array of first electrode structures comprises:
performing an ion implanting process to sidewalls of the array of first electrode structures, such that each first electrode structure has the first uneven sidewall.

17. The method of claim 16, wherein performing the ion implanting process comprises:
implanting phosphorus ions or boron ions to the sidewalls of the array of first electrode structures.

18. The method of claim 16, wherein before forming the array of first electrode structures, the method further comprises:
forming an insulating layer on the array of vertical transistors;
forming a mesh structure in the insulating layer; and
forming an array of through holes each vertically extending through the insulating layer and the mesh structure to expose the array of vertical transistors.

19. The method of claim 18, wherein before performing the ion implanting process, the method further comprises:
depositing one or more conductive materials into the array of through holes to form the array of first electrode structures; and
removing portions of the mesh structure to expose the sidewalls of the array of first electrode structures.

20. A system, comprising:
a memory device configured to store data, the memory device comprising:
an array of vertical transistors; and
an array of vertical capacitors each comprising:
a first electrode structure coupled with a corresponding one of the array of vertical transistors, and
a second electrode structure electrically isolated from the first electrode structure,
wherein the first electrode structure has a first uneven sidewall along a vertical direction and facing the second electrode structure; and
a memory controller electrically connected to the memory device and configured to control the memory device.
